(19) United States
(12) Patent Application Publication
(10) Pub. No.: US 2023/0238814 A1
(43) Pub. Date: Jul. 27, 2023

(54) Charger, charging device, energy supply device and control method of charger

(71) Applicant: Greenworks (Jiangsu) Co., Ltd., Changzhou (CN)

(72) Inventors: Chuntao LU, Changzhou (CN); Yanqiang ZHU, Changzhou (CN); Xuyan XIE, Changzhou (CN); Xi LI, Changzhou (CN); An YAN, Changzhou (CN); Xian ZHUANG, Changzhou (CN); Xiaohui HUO, Changzhou (CN); Zhiyuan LI, Changzhou (CN)

(73) Assignee: Greenworks (Jiangsu) Co., Ltd., Changzhou (CN)

(21) Appl. No.: 18/295,255

(22) Filed: Apr. 3, 2023

Related U.S. Application Data
(63) Continuation of application No. PCT/CN2021/123703, filed on Oct. 14, 2021.

(30) Foreign Application Priority Data
Oct. 16, 2020 (CN) 202011107770.8
Dec. 24, 2020 (CN) 202011550988.0
Dec. 24, 2020 (CN) 202011551200.8
Dec. 24, 2020 (CN) 202011553902.X
Dec. 24, 2020 (CN) 202011553912.3
Dec. 24, 2020 (CN) 202023156169.6
Dec. 24, 2020 (CN) 202023156248.7
Dec. 24, 2020 (CN) 202023156297.0
Dec. 24, 2020 (CN) 202023156550.2
Dec. 24, 2020 (CN) 202023156576.7
Dec. 24, 2020 (CN) 202023159913.8
Dec. 24, 2020 (CN) 202023159937.3
Dec. 24, 2020 (CN) 202023160148.1
Dec. 28, 2020 (CN) 202011582635.9

(51) Int. Cl. H02J 7/00; H05K 7/20

(52) U.S. Cl. CPC H02J 7/0045; H05K 7/20145; H05K 7/20409; H05K 7/20172; H02J 7/0013

(57) ABSTRACT

The disclosure provides a charger, a charging device, an energy supply device and a control method of the charger. The charger comprises a housing, a charging position, a charging port and a first heat dissipation unit. The charger comprises a base and a supporting part. The supporting part is arranged on the base. The charging position is arranged on the base and distributed around the supporting part. The charging port is arranged on the charging position and matched with a battery pack. The first heat dissipation unit is arranged on the supporting part for heat dissipation of the battery pack. With the charger of the disclosure, multiple battery packs can be charged at the same time.

### TECHNICAL FIELD

The disclosure relates to the field of charging technology, in particular to a charger, a charging device, an energy supply device and a control method of the charger.

### BACKGROUND

With the development of economy, household power tools have been used in thousands of households. Even, many users have multiple power tools at the same time, such as blowers, chain saws, electric drills, and so on. These power tools are equipped with one or more battery packs. However, the conventional chargers usually can only charge a single battery pack and cannot charge multiple battery packs at the same time, which may take a long time for the user to charge the battery packs one by one after each use of the power tools. Secondly, when users work outdoors, they occasionally need to use tools other than power tools, and at this time emergency alternating current is needed. However, the inconvenience to users is caused by the inaccessibility of mains supply outdoors.

In view of this, it is indeed necessary to design an improved charger, a charging device, an energy supply device, and a control method of charger to solve the problems mentioned above.

### SUMMARY

The disclosure provides a charger, a charging device, an energy device and a control method of charger, which can charge multiple battery packs at the same time, thereby shortening users' waiting time and improving charging efficiency.

In order to solve the technical problems mentioned above, the disclosure is implemented through the following technical solutions:

The disclosure provides a charger, the charger includes a housing, a charging position, a charging port and a first heat dissipation unit.

The housing defines a base and a supporting part arranged on the base.

The charging position is arranged on the base and distributed around the supporting part.

The charging port is arranged on the charging position and matched with a battery pack.

The first heat dissipation unit is arranged on the supporting part for heat dissipation of the battery pack.

In an embodiment of the disclosure, the supporting part includes:

a first wall, which is arranged opposite to the battery pack, and

a second wall, which is located between two adjacent charging positions.

In an embodiment of the disclosure, the supporting part is provided with:

a first vent, which is arranged on the first wall and used to allow air to flow in and out, and

a second vent, which is arranged on the second wall and used to allow air to flow in and out.

In an embodiment of the disclosure, the charging position includes a first charging position and a second charging position, the first charging position is arranged on one side of the supporting part, the second charging position is arranged on a side opposite to the first charging position, the first wall includes a first side wall and a second side wall, the first vent includes a first side vent hole arranged on the first side wall and a second side vent hole arranged on the second side wall.

In an embodiment of the disclosure, the first charging position, the second charging position and the supporting part are arranged in a same line.

In an embodiment of the disclosure, when the battery pack is connected with the charging position, the battery pack is inclined toward the supporting part.

In an embodiment of the disclosure, there is an angle α between the battery pack and the vertical direction, and the angle α is between 0° and 10°.

In an embodiment of the disclosure, the charging position includes a bearing wall to carry the battery pack, and an angle between the bearing wall and the horizontal plane is between 0° and 10°.

In an embodiment of the disclosure, the charger includes:

a water collection groove, which is arranged on the base,

a drainage channel, which is communicated with the water collection groove to drain the water in the water collection groove out of the housing, and

a terminal assembly, which is arranged on the base, and the water collection groove is located on one or multiple sides of the terminal assembly to collect water in a vicinity of the terminal assembly.

In an embodiment of the disclosure, the housing includes a top wall, a bottom wall arranged opposite to the top wall, and a side wall located between the top wall and the bottom wall, the top wall, the bottom wall, and the side wall jointly form a receiving cavity, the receiving cavity includes a first receiving cavity and a second receiving cavity, and the first receiving cavity houses the first heat dissipation unit.

In an embodiment of the disclosure, the charger further includes:

a circuit component, which is arranged in the second receiving cavity, and

a second heat dissipation unit, which is arranged in the second receiving cavity to dissipate heat for the circuit component.

In an embodiment of the disclosure, a radiating fin is arranged in the second receiving cavity and used to dissipate heat for the circuit component.

In an embodiment of the disclosure, the base is provided with an air inlet and an air outlet, the second heat dissipation unit drives air to enter from the air inlet and discharge from the air outlet, and the flow direction of the airflow is parallel to the radiating fin.

In an embodiment of the disclosure, the first receiving cavity and the second receiving cavity are separated from each other.

In an embodiment of the disclosure, the first heat dissipation unit and the second heat dissipation unit are fans, the first heat dissipation unit is two fans, the second heat dissipation unit is two heat dissipation fans, the air inlet is provided with a fan, and the air outlet is provided with a fan.

In an embodiment of the disclosure, a ratio of a height of the supporting part to a height of the base is greater than 1.5.

In an embodiment of the disclosure, a height of the base is between 4 cm and 8 cm.

In an embodiment of the disclosure, the charger further includes:

a detection unit, which is used to detect a number of charging positions inserted into the battery pack, the detection unit obtaining status information of the battery pack corresponding to each charging position.

When a number of battery packs connected with the charging position is 1, the battery pack at the charging position is charged with acceptable maximum power/current/voltage acceptable by the battery pack,

When the number of battery packs connected with the charging position is greater than 1, a control unit allocates power/current/voltage to the charging positions with the inserted battery pack one by one according to the number of the charging positions with the inserted battery pack and the status information of the battery pack.

In an embodiment of the disclosure, the charger further includes:

a transformer unit, which is connected with an external power supply,

a first charging unit, which is electrically connected to the transformer unit,

a second charging unit, which is electrically connected to the transformer unit, and

a control unit, which is electrically connected with the first charging unit and the second charging unit, the control unit obtaining internal information of the battery pack and controls the first charging unit and the second charging unit to work in series or in parallel according to the internal information.

The disclosure further provides a charger, the charger includes:

a charging position, which is used to charge a battery pack,

an information acquisition unit, which is used to obtain a temperature of the battery pack,

a first heat dissipation unit, which is used for heat dissipation of the battery pack, and

a control unit, which controls the charging position and the first heat dissipation unit to work according to the temperature of the battery pack.

When the temperature of the battery pack is greater than a first temperature threshold, the control unit controls the charging position to stop working and controls the first heat dissipation unit to work to dissipate heat of the battery pack.

The disclosure further provides a control method of charger, the method includes:

obtaining a temperature of a battery pack,

stopping the charger charging and controlling the first heat dissipation unit to dissipate heat of the battery pack when the temperature of the battery pack is greater than or equal to a first temperature threshold,

charging the battery pack by the charger and controlling the first heat dissipation unit to dissipate heat of the battery pack when the temperature of the battery pack is less than the first temperature threshold.

The disclosure further provides a charging device. The charging device includes:

a power input, which is used to electrically connected with an external power source,

a charging part, which is electrically connected with the power input, and

at least one charger, which is detachably connected to the charging part, and the charger includes:

a base,

a supporting part, arranged on the base,

a charging position, arranged on the base and distributed around the supporting part,

a charging port, arranged on the charging position and matched with the battery pack, and

a first heat dissipation unit, which is arranged on the supporting part to dissipate heat of the battery pack.

In an embodiment of the disclosure, the charging device further includes:

an output unit, which is used to output electric power to the outside,

an inverter unit, which is used to invert the electric power obtained by the charging part from the battery pack through the charger into alternating current and output the alternating current through the output unit, and

a control unit.

When the power input is connected with an external power, the control unit controls the charging part to supply power to the charger.

When the power input is disconnected from the external power, the control unit controls the inverter unit to work to output the power obtained by the charging part from the battery pack through the charger via the output unit.

In an embodiment of the disclosure, the output unit includes an alternating current output interface and a direct current output interface.

In an embodiment of the disclosure, the charging part includes a seat, the seat is provided with a first slide rail, the charger is provided with a second slide rail matched with the first slide rail, and when the charger is connected with the charging part, the first slide rail is matched with the second slide rail.

The disclosure further provides an energy supply device. The energy supply device includes:

a battery pack, and

a charger, which is used to charge the battery pack. The charger includes:

a housing, which defines a base and a supporting part arranged on the base,

a charging position, which is arranged on the base and distributed around the supporting part,

a charging port, which is arranged on the charging position and matched with a battery pack, and

a first dissipation unit, arranged on the supporting part for heat dissipation of the battery pack.

The disclosure further provides an energy supply device. The energy supply device includes:

a power input, used to electrically connected with an external power source,

a charging part, electrically connected with the power input,

a battery pack, and

at least one charger, used to charge the battery pack and detachably connected with the charging part. The charger includes:

a base,

a supporting part, arranged on the base,

a charging position, arranged on the base and distributed around the supporting part,

a charging port, arranged on the charging position and matched with the battery pack, and

a first heat dissipation unit, which is arranged on the supporting part for heat dissipation of the battery pack.

As described above, with the charger, charging device, energy supply device, and control method of charger of the disclosure, multiple battery packs can be charged at the same time, thereby shortening users' waiting time and improving charging efficiency.

Of course, any product implementing the disclosure does not need to achieve all the advantages described above at the same time.

### BRIEF DESCRIPTION OF THE DRAWINGS

In order to explain the technical solutions of the embodiments of the disclosure more clearly, the following will briefly introduce the drawings used in the description of the embodiments. Obviously, the drawings in the following description are only some embodiments of the disclosure. For those of ordinary skill in the art, other drawings can be obtained from these drawings without creative work.

FIG. 1 is a perspective structural schematic view of a charger of the disclosure.

FIG. 2 is an exploded perspective view of the charger shown in FIG. 1.

FIG. 3 is a cross-sectional view of the charger shown in FIG. 1.

FIG. 4 is a perspective schematic view of the charger shown in FIG. 1 from another angle.

FIG. 5 is a perspective schematic view of an energy supply device of the disclosure.

FIG. 6 is a perspective structural schematic view of an energy supply device of the disclosure.

FIG. 7 is a cross-sectional view of the energy supply device shown in FIG. 6.

FIG. 8 is a block diagram of a module of a charging device of the disclosure.

FIG. 9 is a perspective structural schematic view of a charging device of the disclosure.

FIG. 10 is a cross-sectional view of the charging device shown in FIG. 9.

FIG. 11 is a cross-sectional view of the charging device shown in FIG. 9 along AA direction.

FIG. 12 is a partially enlarged view of FIG. 11.

FIG. 13 is a perspective structural schematic view of another embodiment of a housing.

FIG. 14 is an exploded view of the housing shown in FIG. 13.

FIG. 15 is a perspective structural schematic view of a charging device of a second embodiment of the disclosure.

FIG. 16 is an exploded schematic view of a housing, a terminal assembly, a base bracket, and a sealing component.

FIG. 17 is a perspective structural schematic view indicating the terminal assembly and the base bracket matching with each other.

FIG. 18 is a partial enlarged schematic view of the terminal assembly and the base bracket from another angle.

FIG. 19 is a schematic flowchart of a control method of a charging device of the disclosure.

FIG. 20 is a block diagram of a charger of the disclosure.

FIG. 21 is a schematic flowchart of a control method of a charger of the disclosure.

FIG. 22 is a schematic flowchart of operation S204.

FIG. 23 is a schematic flowchart of operation S205.

FIG. 24 is a block diagram of a charger of the disclosure.

FIG. 25 is a schematic flowchart of a control method of a charger of the disclosure.

FIG. 26 is a schematic flowchart of operation S303.

FIG. 27 is a schematic view of a charger of the disclosure.

FIG. 28 is a circuit diagram when a charger of the disclosure charges a single-voltage battery pack.

FIG. 29 is a circuit diagram when a charger of the disclosure charges a double-voltage battery pack in series.

FIG. 30 is a circuit diagram when a charger of the disclosure charges a double-voltage battery pack in parallel.

FIG. 31 is a schematic view of a charger of the second embodiment of the disclosure.

FIG. 32 is a flowchart of a control method of a charger of the disclosure.

FIG. 33 is a schematic flowchart of operation S401.

FIG. 34 is a schematic flowchart of operation S403.

FIG. 35 is a block diagram of a transformer module of the disclosure.

FIG. 36 is a block diagram of a detection circuit.

FIG. 37 is a block diagram of a secondary over-current and over-voltage detection circuit.

FIG. 38 is a schematic flowchart of a control method of a voltage transformation of the disclosure.

FIG. 39 is a schematic perspective view of a charging device of the disclosure.

FIG. 40 is a perspective view of a charging device of the disclosure witha top cover and a charger removed.

FIG. 41 is a partially enlarged view of FIG. 40.

FIG. 42 is a schematic view of the charging device shown in FIG. 39 when a first connecting interface is erected.

FIG. 43 is a schematic view of the first connecting interface of the charging device shown in FIG. 39 connected with the battery pack.

FIG. 44 is a cross-sectional view of FIG. 40 along a direction CC.

FIG. 45 is a perspective schematic view of the charger from another angle.

FIG. 46 is a perspective schematic view of the charging device of the second embodiment of the disclosure without the charger.

FIG. 47 is a schematic view of the charger of the second embodiment of the disclosure.

FIG. 48 is a perspective schematic view of a charging device of a third embodiment of the disclosure without the charger.

FIG. 49 is a schematic view of a charger of the third embodiment of the FIG. 50 is a perspective schematic view of an energy supply device of the disclosure.

### DETAILED DESCRIPTION

In the following, the technical solutions in the embodiments of the disclosure will be described clearly and completely in conjunction with the drawings in the embodiments of the disclosure. Obviously, the described embodiments are only a part of the embodiments of the disclosure, rather than all the embodiments. Based on the embodiments of the disclosure, all other embodiments obtained by those of ordinary skill in the art without creative work are all within the protection scope of the disclosure.

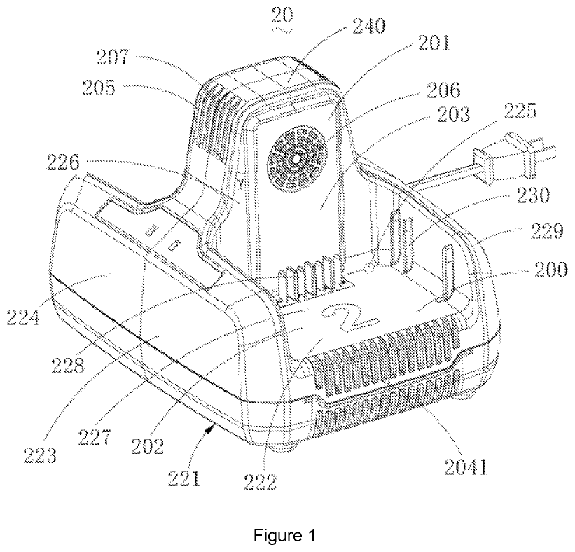

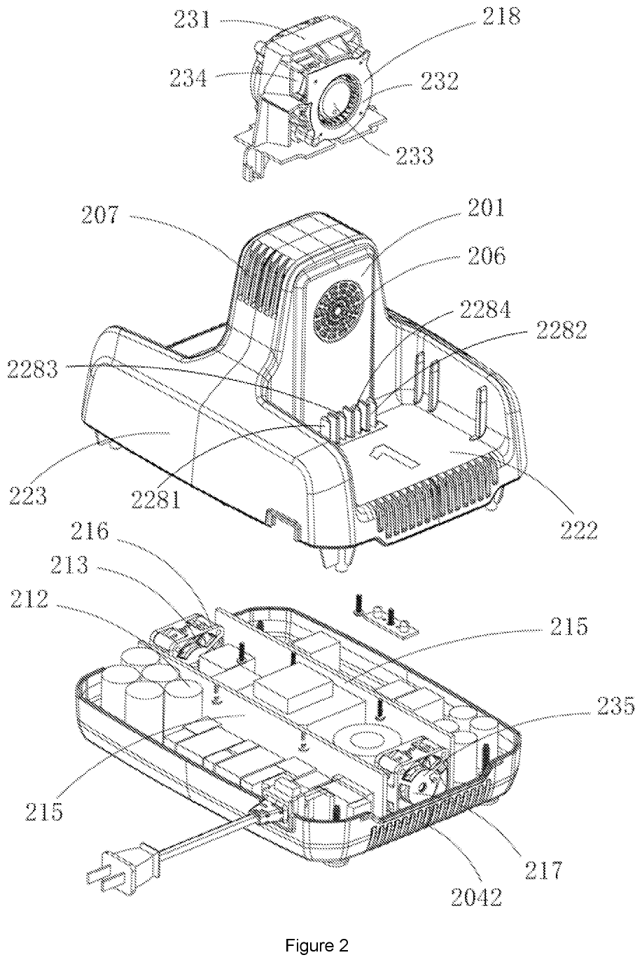

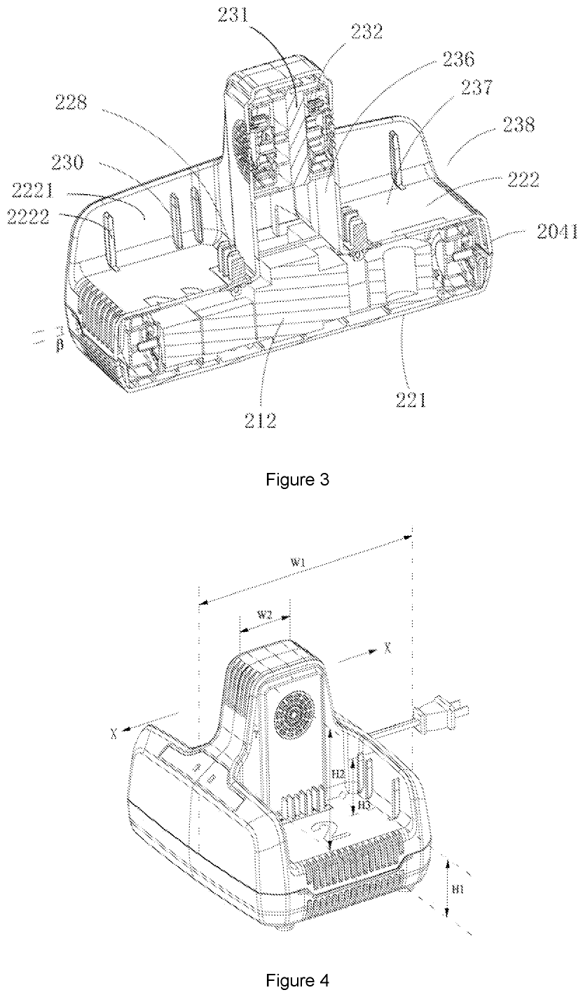

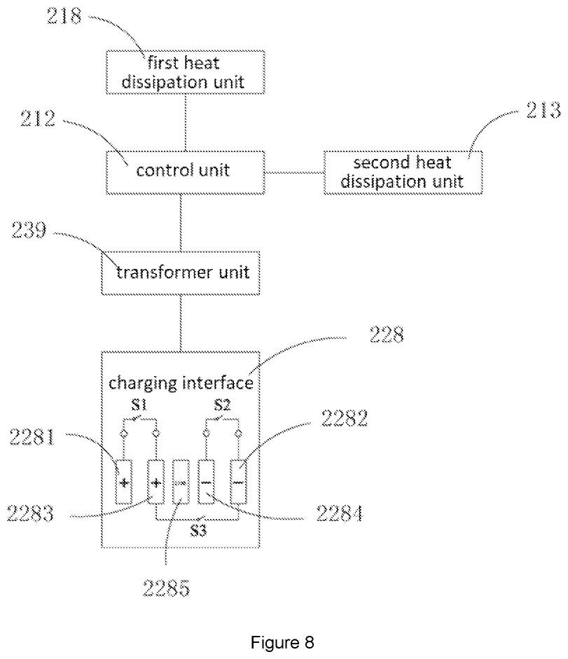

Please refer to FIG. 1, FIG. 2, FIG. 3 and FIG. 8. The disclosure provides a charger 20 which can be used to charge a single-voltage battery pack and a multi-voltage battery pack. The charger 20 includes a housing 224, a first heat dissipation unit 218 for heat dissipation of the battery pack, a transformer unit 239 located in the housing 224, a control unit 212, and a second heat dissipation unit 213 for heat dissipation of the control unit 212. The transformer unit 239 is used to connect with an external power source to obtain power and convert the power into a required voltage.

Please refer to FIG. 1 through FIG. 3 and FIG. 7, the housing 224 includes a base 200 and a supporting part 201 arranged on the base 200. The base 200 includes a bottom wall 221, a top wall 222 arranged opposite to the bottom wall 221, and a side wall 223 located between the bottom wall 221 and the top wall 222. The bottom wall 221, the top wall 222 and the side wall 223 jointly define a receiving cavity 2333 for housing the control unit 212 and the second heat dissipation unit 213. In order not to affect the heat dissipation effect of the second heat dissipation unit 213 on the control unit 212, and also to make the housing 224 not bulky, the height of the base 200 is set from 4 cm to 8 cm. Preferably, the height of the base 200 is from 4.5 cm to 5.5 cm. The base 200 is further provided with a charging position 202 for charging the battery pack. The charging position 202 includes a bearing wall 227 for carrying the battery pack, a charging port 228 matched with the battery pack, and a fence 229. The bearing wall 227, the fence 229 and the supporting part 201 jointly form a connecting cavity 237 for housing the battery pack. Preferably, an opening 238 is further arranged at one end of the connecting cavity 237 away from the supporting part 201 to enhance the ventilation and heat dissipation performance of the battery pack. In this embodiment, the bearing wall 227 is part of the top wall 222. The charging port 228 is arranged on the bearing wall 227. Since the charging port 228 is arranged on the bearing wall 227, the reliability of the electrical connection between the charging port 228 and the battery pack can be effectively ensured through the gravity of the battery pack, and slight external forces (for example, vibration) will not cause poor contact between the charging port 228 and the battery pack. Moreover, since the gravity of the battery pack is completely borne by the bearing wall 227, the battery pack will not cause damage to the charging port 228. The fence 229 is used to limit the position of the battery pack to prevent the battery pack from tilting, thereby avoiding damage to the charging port 228. In this embodiment, the fence 229 is formed by extending the side wall 223 upward. Preferably, a side of the fence 229 facing the connecting cavity 237 is further provided with a guiding component 230 matched with the battery pack to guide the battery pack to be smoothly inserted into the connecting cavity 237. In this embodiment, the guiding component 230 is a guiding block. However, it is understandable that the structure of the guiding component 230 has many types, for example, it may be a guiding groove or the like, which is not limited here. In an embodiment of the disclosure, a limiting wall 2221 is further arranged on one or more sides of the charging position 202 to prevent the battery pack located on the charging position 202 from accidentally separating from the charging position 202. Further, a sliding groove 2222 is also arranged on the limiting wall 2221 to match the sliding rail on the battery pack shell, thereby further fixing the battery pack.

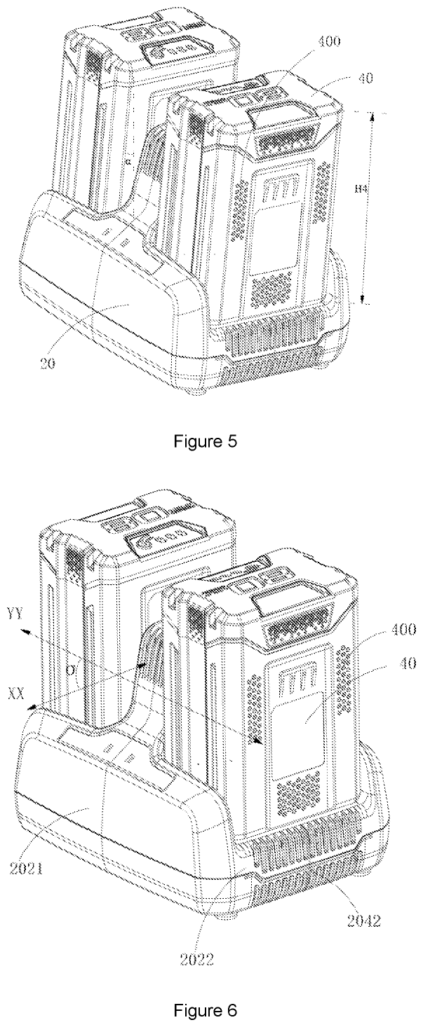

Please refer to FIG. 1 through FIG. 5, in order to enable the battery pack to be inserted into the connecting cavity 237 stably, preferably, the charging position 202 is arranged such that when the battery pack is connected with the charging position 202, the battery pack inclines toward the supporting part 201. At this time, as shown in FIG. 5, there is an angle α between the battery pack and vertical direction, and the angle α is between 0° and 10°. The bearing wall 227 is arranged obliquely, and an angle between the bearing wall 227 and a horizontal plane is β (as shown in FIG. 3). The angle β is between 0° to 10°. At this time, a drainage hole 225 is arranged at the intersection of a first wall 203 and the bearing wall 227. With this arrangement, when the battery pack is used in rainy weather, the water flowing from the battery pack into the connecting cavity 237 can be discharged from the drainage hole 225 to the outside of the charger 20, thereby avoiding the risk of short circuit.

Please refer to FIG. 1, FIG. 2, FIG. 3, and FIG. 6, the supporting part 201 is arranged in the middle of the base 200, and a plurality of charging positions 202 are distributed around the supporting part 201. In this embodiment, the number of charging positions 202 is two, and the two charging positions 202 are symmetrically distributed on both sides of the supporting part 201. Specifically, please refer to FIG. 6 together. The charging position 202 includes, for example, a first charging position 2021 and a second charging position 2022 arranged opposite to the first charging position 2021. The first charging position 2021 and the second charging position 2022 are arranged along a direction YY. The supporting part 201 is located between the first charging position 2021 and the second charging position 2022, so that the first charging position 2021, the supporting part 201, and the second charging position 2022 are collinear. An air inlet/outlet direction of a second vent 207 of the first charging position 2021 and an air inlet/outlet direction of a second vent 207 of the second charging position 2022 are respectively located on different sides of the housing 224. Preferably, please refer to FIG. 6, there is an angle α between the direction YY and the air inlet/outlet direction XX of the second vent 207 of the first charging position 2021 or the air inlet/outlet direction XX of the second vent 207 of the second charging position 2022. Preferably, the angle α is between 30° and 90°. In this embodiment, the first charging position 2021 and the first ventilation fan 232, the second charging position 2022 and the first ventilation fan 232 are symmetrical about the direction YY, and are located on the midpoint plane of the housing 224 along the direction YY. When the number of charging positions 202 is greater than 2, preferably, the charging positions 202 form a regular polygon. The supporting part 201 includes a first wall 203 facing the battery pack, a second wall 205 located between two adjacent charging positions 202, and a third wall 240 arranged opposite to the top wall 222. The third wall 240 is located at an end of the second wall 205 away from the top wall 222. The first wall 203 is provided with a first vent 206 facing the battery pack, and the second wall 205 is provided with a second vent 207 corresponding to the first vent 206 and located between two adjacent charging positions 202. The first vent 206 is used for air inlet/outlet, and the second vent 207 is used for air outlet/inlet. The first wall 203 includes a first side wall and a second side wall, the first side wall is facing the first charging position 2021, and the second side wall is facing the second charging position 2022. The first vent 206 includes a first side vent hole and a second side vent hole, the first side vent hole is arranged on the first side wall, and the second side vent hole is arranged on the second side wall. The first wall 203, the second wall 205 and the third wall 240 jointly form a housing cavity 236, and the first heat dissipation unit 218 is housed in the housing cavity 236. In order to enhance the structural stability of the supporting part 201, preferably, a reinforcing rib 226 is further arranged between the supporting part 201 and the fence 229. The reinforcing rib 226 gradually extends from the top of the supporting part 201 to the fence 229. In order to prevent the reinforcing rib 226 from affecting the ventilation performance of the battery pack, preferably, a angle γ between the side wall of the reinforcing rib 226 away from the supporting part 201 and the height direction of the supporting part 201 (as shown in FIG. 1) is between 8° and 14°.

Please refer to FIG. 1. In this embodiment, the first wall 203 is perpendicular to a horizontal plane. However, it can be understood that in other embodiments, the first wall 203 may also be arranged perpendicular to the bearing wall 227. With this arrangement, the projection area of the first vent 206 on the battery pack is maximized, so that the battery pack has a better ventilation and heat dissipation effect.

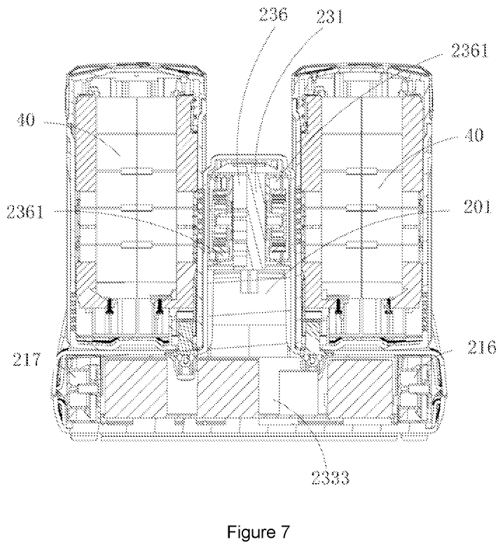

Please refer to FIG. 2 and FIG. 3, the first heat dissipation unit 218 is arranged in the housing cavity 236 to dissipate heat for the battery pack. The first heat dissipation unit 218 includes a bracket 231 and a first ventilation fan 232 arranged on the bracket 231. Specifically, the first ventilation fan 232 is fixedly arranged on the supporting part 201 and is located in the housing cavity 236. In order to avoid mutual interference among the plurality of first ventilation fans 232 located in the housing cavity 236, preferably, please refer to FIG. 7, the bracket 231 is arranged in the housing cavity 236 to divide the housing cavity 236 into a plurality of housing grooves 2361. Each first ventilation fan 232 is located in one housing groove 2361, thereby preventing mutual interference between the multiple first ventilation fans 232. The number of the first ventilation fans 232 is the same as the number of the charging positions 202 to correspond to each charging position 202. The first ventilation fan 232 includes a first air opening 233 matched with the first vent 206 and a second air opening 234 matched with the second vent 207. An air inlet/outlet direction of the first air opening 233 is parallel to the axis of the first ventilation fan 232, and an outlet/inlet direction of the second air opening 234 is perpendicular to the axis of the first ventilation fan 232. When the first ventilation fan 232 rotates forward, airflow flows in from the first vent 206 and the first air opening 233 under the action of the first ventilation fan 232, and then flows out from the second air opening 234 and the second vent 207. When the first ventilation fan 232 rotates backward, the airflow flows in from the second vent 207 and the second air opening 234 under the action of the first ventilation fan 232, and then flows out from the first air opening 233 and the first vent 206. Preferably, when the first ventilation fan 232 rotates forward, since the first vent 206 is facing the battery pack, the second vent 207 is located between the two adjacent charging positions 202, which can effectively prevent air discharged from the second vent 207 from flowing back to the battery pack. In this embodiment, the second vent 207 is arranged on the second wall 205 so that the air outlet direction of the second vent 207 is parallel to the horizontal plane. However, it can be understood that in other embodiments, the second vent 207 may also be arranged on the third wall 240 so that the second vent 207 discharges air from a top of the housing 224. This arrangement can more effectively prevent the air discharged from the second vent 207 from flowing back to the battery pack, thereby effectively improving the heat dissipation effect of the battery pack. In addition, in this embodiment, the housing cavity 236 and the receiving cavity 2333 are not communicated with each other. Since the receiving cavity 2333 and the housing cavity 236 are not communicated, a ventilation passage formed by the first vent 206, the first ventilation fan 232, and the second vent 207 does not interfere with a heat dissipation passage formed by an air inlet 131, a heat dissipation fan 41, and an air outlet 132, thereby improving the heat dissipation effect. However, it can be understood that in other embodiments, the housing cavity 236 and the receiving cavity 2333 may also be arranged to communicate with each other.

Please refer to FIG. 1 to FIG. 4, in order to enable the first heat dissipation unit 218 to efficiently dissipate heat for the battery pack, a ratio of a height H2 of the supporting part 201 to a height H1 of the base 200 is greater than 1.5. At the same time, in order to avoid a negative effect of the supporting part 201 on heat dissipation of the battery pack, preferably, in the air outlet/inlet direction XX (as shown in FIG. 6) of the second vent 207, a ratio of a width W2 of the supporting part 201 to a width W1 of the base 200 is less than 0.6. In order to ensure that the housing cavity 236 has enough space to house the first heat dissipation unit 218, preferably, the ratio of the width W2 of the supporting part 201 to the width W1 of the base 200, for example, ranges from 0.35 to 0.5. In order to prevent the fence 229 from negatively affecting the heat dissipation of the battery pack, a ratio of a height H3 of the fence 229 to the height H1 of the base 200 is, for example, ranges from 0.5 to 1. In order to enable the fence 229 play a better limiting function and at the same time enable the overall appearance of the charger 20 coordinated, preferably, the ratio of the height H3 of the fence 229 to the height H1 of the base 200, for example, ranges from 0.55 to 0.6.

Please refer to FIG. 1 through FIG. 3 and FIG. 7, the control unit 212 is housed in the receiving cavity 2333 for controlling the charging station 202, the first heat dissipation unit 218, and the second heat dissipation unit 213 to work. In this embodiment, the control unit 212 is a control circuit board with various electronic components. However, it can be understood that in other embodiments, the control unit 212 may also be other control modules. The disclosure does not limit the specific structure of the control unit 212. The second heat dissipation unit 213 includes a heat dissipation fan 235 arranged in the receiving cavity 2333, and the heat dissipation fan 235 includes a first heat dissipation fan 216 and a second heat dissipation fan 217. The side wall 223 is provided with a first air vent 2041 matched with the first dissipation fan 216 and a second air vent 2042 matched with the second dissipation fan 217. The first heat dissipation fan 216 and the second heat dissipation fan 217 are used to drive external air to enter from the first air vent 2041, flow through the control unit 212, and be discharged from the second air vent 2042, so as to dissipate heat of the control unit 212. Of course, it can also be configured that: the first dissipation fan 216 and the second dissipation fan 217 drive external air to enter from the second air vent 2042, flow through the control unit 212, and be discharged from the first air vent 2041. A radiating fin 215 is housed in the receiving cavity to assist the control unit 212 to dissipate heat. The number of the radiating fin 215 can be set as needed. In this embodiment, the connection line of the first air vent 2041 and the second air vent 2042 is parallel to the radiating fin 215, so as to enhance the heat dissipation efficiency of the second heat dissipation unit 213. Preferably, the first heat dissipation unit 218 and the second heat dissipation unit 213 are independent of each other, so that an air flow path of the first heat dissipation unit 218 and an air flow path of the second heat dissipation unit 213 do not interfere with each other.

Please refer to FIG. 1 through FIG. 4 and FIG. 8, the charging port 228 includes a charging terminal group, a communication terminal 2285 and a switching module. The control unit 212 communicates with the battery pack through the communication terminal 2285 to obtain internal information of the battery pack. The internal information includes type information, charging requirements, charging voltage information, charging current information of the battery pack, and so on. The type information is used to indicate that the battery pack is a single-voltage battery pack, a multi-voltage battery pack, etc. The charging requirement is used to indicate that the multi-voltage battery pack needs to charge several battery cell groups in series or in parallel. The charging terminal group includes a first charging terminal pair electrically connected with one battery cell group of the battery pack and a second charging terminal pair electrically connected with another battery cell group of the battery pack. The first charging terminal pair includes a first positive electrode 2281 and a first negative electrode 2282. The second charging terminal pair includes a second positive electrode 2283 and a second negative electrode 2284. The switching module is used to change the series-parallel relationship between the first charging terminal pair and the second charging terminal pair. The switching module includes a first switch S1, a second switch S2, and a third switch S3. One end of the first switch S1 is connected to the first positive electrode 2281, and the other end of the first switch S1 is connected to the second positive electrode 2283. One end of the second switch S2 is connected to the first negative electrode 2282, and the other end of the second switch S2 is connected to the second negative electrode 2284. One end of the third switch S3 is connected to the first negative electrode 2282, and the other end of the third switch S3 is connected to the second positive electrode 2283. The first switch S1, the second switch S2, and the third switch S3 may be electronic switch tubes MOSFET. In this embodiment, the switching module realizes series-parallel switching through a MOS transistor. However, it can be understood that there are various structures for realizing the function of the switching module, which is not limited by the disclosure.

Please refer to FIG. 1 through FIG. 4 and FIG. 8, the charging port 228 has a first state and a second state. When the charging port 228 is in the first state, the first switch S1 and the second switch S2 are open, and the third switch S3 is closed. At this time, the charging port 228 is matched with the battery cell group of the battery pack, so that the battery cell group of the battery pack can be charged after connecting in series. When the charging port 228 is in the second state, the first switch S1 and the second switch S2 are closed, and the third switch S3 is open. At this time, the charging port 228 is matched with the battery cell group of the battery pack, so that the battery cell group of the battery pack can be charged after connecting in parallel. The control unit 212 controls the charging port 228 to work in the first state or the second state according to the obtained internal information. When the battery pack is a single-voltage battery pack, the control unit 212 controls the charging port 228 to be in the second state. At this time, the second charging terminal pair is in an idle state, and the first positive electrode 2281 and the first negative electrode 2282 are respectively connected with two ends of the transformer unit 239. When the battery pack is a multi-voltage battery pack and needs to be charged in series, the control unit 212 controls the charging port 228 to be in the first state. At this time, the first positive electrode 2281 and the second negative electrode 2284 are respectively connected with the two ends of the transformer unit 239, and the first negative electrode 2282 and the second positive electrode 2283 are electrically connected. When the battery pack is a multi-voltage battery pack and needs to be charged in parallel, the control unit 212 controls the charging port 228 to be in the second state. At this time, the first positive electrode 2281 and the second positive electrode 2283 are connected with one end of the transformer unit 239, and the first negative electrode 2282, the second negative electrode 2284 is connected with the other end of the transformer unit 239. The control unit 212 controls the transformer unit 239 to output a charging voltage matching the battery pack according to internal information.

Please refer to FIG. 1, the charger 20 provided by the disclosure can charge multiple battery packs at the same time, thereby shortening users' waiting time and improving the charging efficiency. Moreover, since the charging port 228 is arranged on the bearing wall 227 that carries the battery pack, the reliability of the electrical connection between the charging port 228 and the battery pack can be effectively ensured, and the charging port 228 will not be damaged at the same time. Secondly, when the battery pack is connected with the charging station 202, the battery pack inclines toward the supporting part 201 and resists the supporting part 201, so that the battery pack can be inserted into the connecting cavity 237 stably.

Please refer to FIG. 4 and FIG. 6. The disclosure also provides an energy supply device, which includes the battery pack 40 and the charger 20. In addition, a ratio of a height H2 of the supporting part 201 of the charger 20 to a height H4 of the battery pack 40 ranges, for example, from 0.3 to 0.8. This arrangement not only enables the battery pack 40 to be stably housed in a connecting cavity 114, but also enables the battery pack 40 to have a better ventilation and heat dissipation effect without affecting the ventilation and heat dissipation performance of the battery pack 40 due to the high supporting part 201. The battery pack 40 is provided with a heat dissipation hole 400 matched with the first vent 206 to facilitate the first heat dissipation unit 218 to dissipate heat for the battery pack 40.

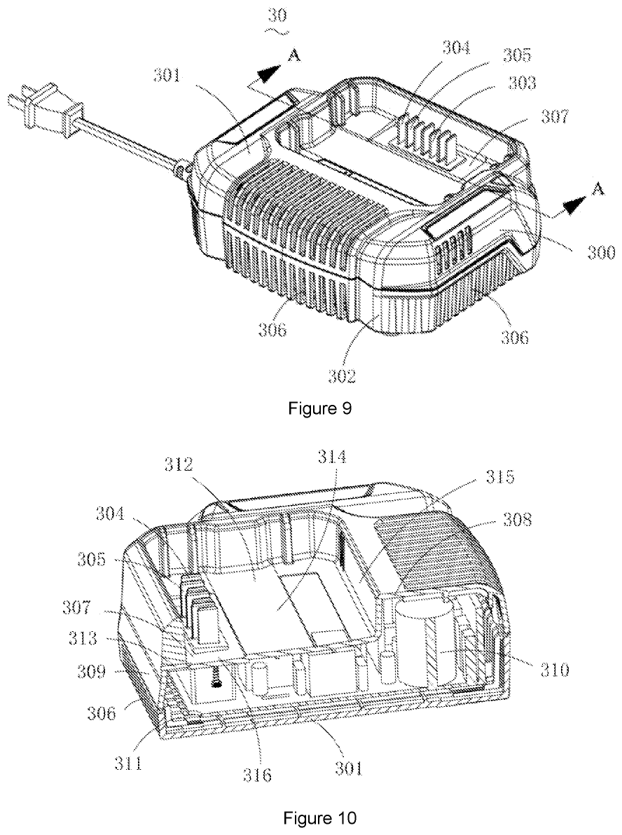

Please refer to FIG. 9 and FIG. 10. The disclosure also provides a charging device 30; the charging device 30 includes a housing 300, a terminal assembly 303 arranged on the housing 300, and a charging assembly 310 housed in the housing 300. The charging assembly 310 includes a charging circuit, a control circuit board, etc., for transmitting the obtained external power to the device to be charged. The device to be charged is usually a battery pack.

Please refer to FIG. 9 and FIG. 10, the housing 300 includes a bottom wall 301, a top wall 308 arranged opposite to the bottom wall 301 and opposite to the device to be charged, and a side wall 313 located between the bottom wall 301 and the top wall 308. The bottom wall 301, the top wall 308 and the side wall 313 jointly form a receiving cavity for housing the charging assembly 310. The bottom wall 301 is provided with a plurality of ventilation holes 311, and the side wall 313 is provided with a plurality of ventilation holes 306. When the charging device 30 is working, the heat generated by the charging assembly 310 is dissipated out of the receiving cavity through the ventilation holes 311 and the ventilation holes 306. Preferably, the cross section of the ventilation hole 311 and the ventilation hole 306 is a long and narrow rectangle. Preferably, at an intersection of the bottom wall 301 and the side wall 313, the ventilation hole 311 and the ventilation hole 306 communicate with each other, thereby forming a large ventilation hole with an L-shaped cross-section. The top wall 308 is provided with a connecting cavity 312 matched with the device to be charged, a water collection groove 307 and a drainage channel 313 communicating with the water collection groove 307. The connecting cavity 312 is used for housing and fixing the device to be charged to prevent the device to be charged from shaking, and also to prevent the terminal assembly 303 from being damaged due to an oblique insertion of the device to be charged by the user. The connecting cavity 312 includes a cavity bottom wall 314 opposite to the device to be charged and a cavity side wall 315 perpendicular to the cavity bottom wall 314. The terminal assembly 303 is fixedly arranged on the cavity bottom wall 314. The water collection groove 307 is arranged on the cavity bottom wall 314 and located on one or more sides of the terminal assembly 303 to collect water in a vicinity of the terminal assembly 303. In this embodiment, the water collection groove 307 surrounds the terminal assembly 303, but in other embodiments, the water collection groove 307 can also be arranged to surround or half-surround the terminal assembly 303.

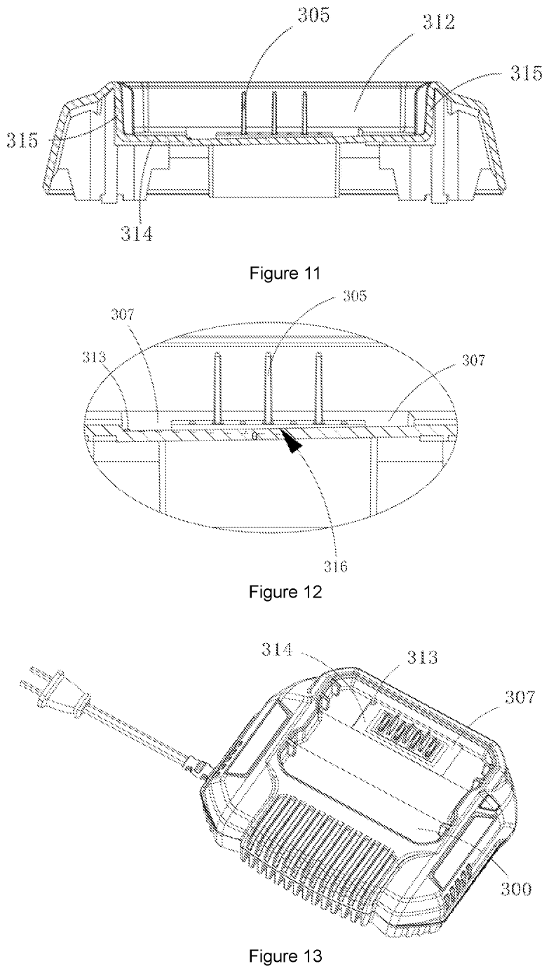

Please refer to FIG. 11 and FIG. 12 together, the water collection groove 307 is inclined from an end away from the drainage channel 313 to an end close to the drainage channel 313 so that water can converge toward the drainage channel 313 under the action of gravity. An angle θ between a bottom wall 316 of the water collection groove 307 and the horizontal plane is, for example, between 5° and 60°. Preferably, the angle θ is, for example, between 5° and 10°. Please refer to FIG. 10, the drainage channel 313 is communicated with the water collection groove 307 to drain the water in the water collection groove 307 out of the housing 300. One end of the drainage channel 313 communicates with the water collection groove 307, and the other end passes through the side wall 313 to communicate with the outside. Preferably, an angle between the drainage channel 313 and the horizontal plane is not less than 5°. With this arrangement, water converging at the entrance of the drainage channel 313 can flow out of the housing 300 along the drainage channel 313 under the action of gravity.

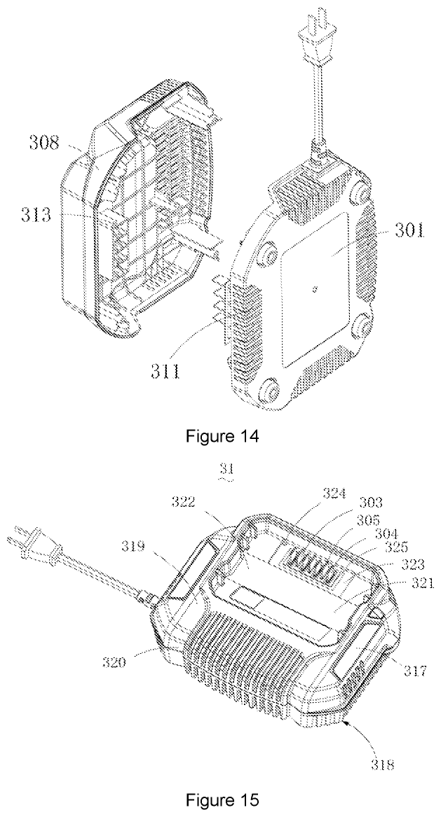

Please refer to FIG. 9 and FIG. 12 together, the top wall 308 is provided with a connecting cavity 312, but it is understandable that in other embodiments, the top wall 308 may not be provided with a connecting cavity 312, and the water collection groove 307 is directly arranged on the top wall 308 at this time. Although in this embodiment, the drainage channel 313 is arranged through the side wall 313, it is understood that in other embodiments, the drainage channel 313 may also be arranged through the bottom wall 301. For example, please refer to FIG. 13 and FIG. 14, the drainage channel 313 is formed through denting inward from the bottom wall 316 of the water collection groove 307, and penetrates the bottom wall 301 to drain the water in the water collection groove 307 out of the housing 300. Preferably, the drainage channel 313 is perpendicular to the bottom wall 301. Since the bottom wall 301 is provided with ventilation holes 311, in practice, the drainage channel 313 only needs to pass through the charging assembly 310 and directly face the ventilation holes 311, so that the water discharged from the drainage channel 313 is discharged from the ventilation hole 311 out of the housing 300.

Please refer to FIG. 9 and FIG. 10, the terminal assembly 303 includes a plurality of conductive terminals 304 and separation ribs 305 located between adjacent conductive terminals 304. The conductive terminals 304 and the bottom wall 301 are injection molded into one body, and organic polymer nano films are arranged on the conductive terminals 304 to protect the conductive terminals 304. The conductive terminals 304 are connected to the charging assembly 310 so that the external power obtained by the charging assembly 310 is transmitted to the device to be charged through the conductive terminals 304. The separation ribs 305 are located between the adjacent conductive terminals 304 to separate the adjacent conductive terminals 304, which prevent water on the conductive terminals 304 from forming a water film between the adjacent conductive terminals 304, thereby preventing a short circuit. Preferably, the separation ribs 305 are made of insulating plastic and are integrally molded with the bottom wall 301.

Please refer to FIG. 9 through FIG. 14, since the charging device 30 of the disclosure is provided with a water collection groove 307 arranged on one or more sides of the terminal assembly 303 and a drainage channel communicated with the water collection groove 307, the charging device 30 can quickly collect water entering the connecting cavity 312 and discharge it out of the housing 300, thereby effectively preventing water from contacting the terminal assembly 303 and avoiding safety accidents. At the same time, since the water collection groove 307 is located on one or more sides of the terminal assembly 303, water condensed on the terminal assembly 303 in the air can be collected and discharged out of the housing 300, thereby preventing water from entering the charging device 30. In addition, since there are separation ribs 305 between the adjacent conductive terminals 304, condensed water on the conductive terminals 304 can effectively prevent the formation of a water film between the adjacent conductive terminals 304, thereby improving the safety performance of the charging device 30.

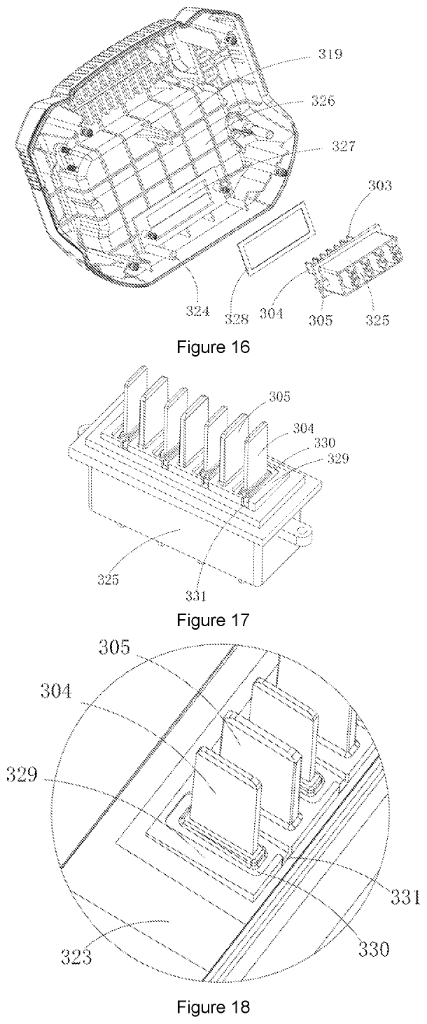

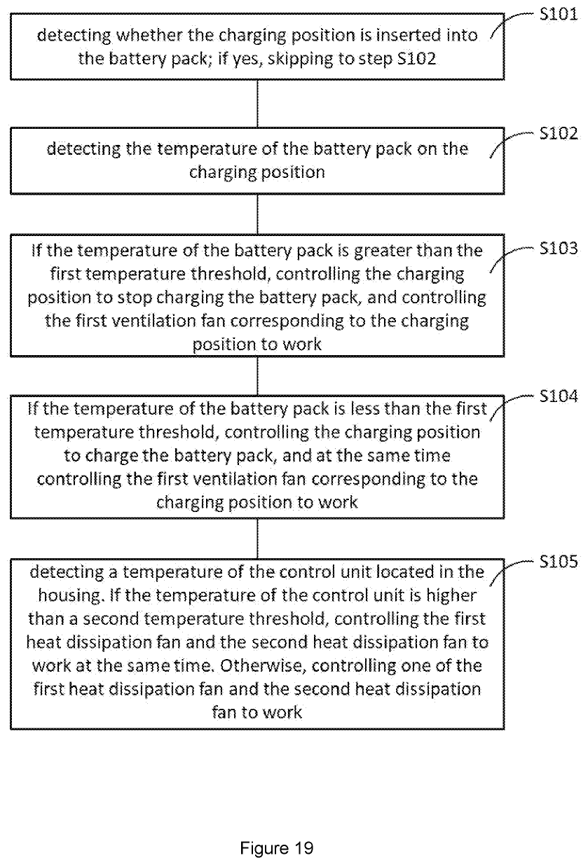

Please refer to FIG. 15, in another embodiment of the disclosure, a charging device 31 is provided. A structure of the charging device 31 is substantially the same as a structure of the charging device 30. Please refer to FIG. 16, FIG. 17, and FIG. 18, the charging device 31 includes a housing 317, a terminal assembly 303, a base bracket 325 for holding the terminal assembly 303, a sealing component 328 matched with the base bracket 325, and a charging assembly 310. The housing 317 includes a bottom wall 318, a top wall 319 arranged opposite to the bottom wall 318, and a side wall 320 located between the bottom wall 318 and the top wall 319. The bottom wall 318, the top wall 319 and the side wall 320 jointly form a receiving cavity 326 for housing the charging assembly 310 and the base bracket 325. The top wall 319 is provided with a connecting cavity 321 matched with the device to be charged. A cavity bottom wall 322 of the connecting cavity 321 is provided with a mounting groove 327, a main water collection groove 323 located on one or more sides of the mounting groove 327, and a drainage channel 324 communicated with the main water collection groove 323. The mounting groove 327 penetrates the cavity bottom wall 322 and communicates with the receiving cavity 326. In this embodiment, the main water collection groove 323 surrounds the mounting groove 327, but it is understood that in other embodiments, the main water collection groove 323 may also be arranged to surround or half-surround the mounting groove 327. The drainage channel 324 communicates with the main water collection groove 323 to drain water in the main water collection groove 323 out of the housing 317. Preferably, the main water collection groove 323 is inclined from a side far from the drainage channel 324 to a side close to the drainage channel 324, so that water can converge toward the drainage channel 324 under the action of gravity, thereby facilitating drainage. The terminal assembly 303 may be detachably fixedly arranged on the base bracket 325, or may be integrated with the base bracket 325 by injection molding. The base bracket 325 is fixedly arranged on the mounting groove 327 by screws, so that the terminal assembly 303 can pass through the mounting groove 327 and at least partially be located in the connecting cavity 321. The base bracket 325 is higher than the main water collection groove 323 so that water converging in the main water collection groove 323 is separated from the terminal assembly 303. Preferably, the base bracket 325 is higher than the main water collection groove 323 and is inclined to the main water collection groove 323 so that water on the base bracket 325 can converge to the main water collection groove 323 under the action of gravity. Preferably, an angle between a top wall 329 of the base bracket 325 and the horizontal plane is not less than 5°. The base bracket 325 is also provided with a sub water collection groove 330 communicating with the main water collection groove 323. The sub water collection groove 330 is located between the adjacent conductive terminals 304 to quickly collect condensed water on the conductive terminals 304. In this embodiment, the sub water collection groove 330 surrounds the conductive terminals 304 and is provided with an outlet 331 communicating with the main water collection groove 323. However, it can be understood that in other embodiments, the sub water collection groove 330 may also be arranged to surround or semi-surround the conductive terminals 304. In addition, although in this embodiment, the housing 317 is provided with the main water collection groove 323, in other embodiments, the housing 317 may not be provided with the main water collection groove 323, and the drainage channel 324 directly communicates with the sub water collection groove 330. The sealing component 328 is located between the base bracket 325 and the mounting groove 327 to enhance the sealing performance between the terminal assembly 303 and the housing 317 and prevent water from entering the charging device 31 along a gap between the base bracket 325 and the mounting groove 327 internal.

Please refer to FIG. 9 and FIG. 15, the charging device 30 or a drainage device (including a water collection groove and a drainage channel) on the charging device 31 provided by the disclosure can be directly applied to the charger 20. And the disclosure also provides an energy supply device which includes a battery pack and a charging device 30 or a charging device 31, or includes a charger, a battery pack, and a charging device 30 or a charging device 31.

Please refer to FIG. 6, the disclosure also provides a control method of charger, the method includes the following operations:

S101: detecting whether a battery pack is inserted into a charging position, if yes, skipping to operation S102.

S102: detecting a temperature of the battery pack on the charging position.

S103: controlling the charging position to stop charging the battery pack and controlling a first ventilation fan corresponding to the charging position to work if the temperature of the battery pack is greater than a first temperature threshold. Wherein, the first temperature threshold can be set as required.

S104: controlling the charging position to charge the battery pack, and at the same time controlling the first ventilation fan corresponding to the charging position to work if the temperature of the battery pack is less than the first temperature threshold.

S105: detecting a temperature of a control unit located in the housing. If the temperature of the control unit is higher than a second temperature threshold, controlling the first heat dissipation fan and the second heat dissipation fan to work at the same time. Otherwise, controlling one of the first heat dissipation fan and the second heat dissipation fan to work. The second temperature threshold can be set as required.

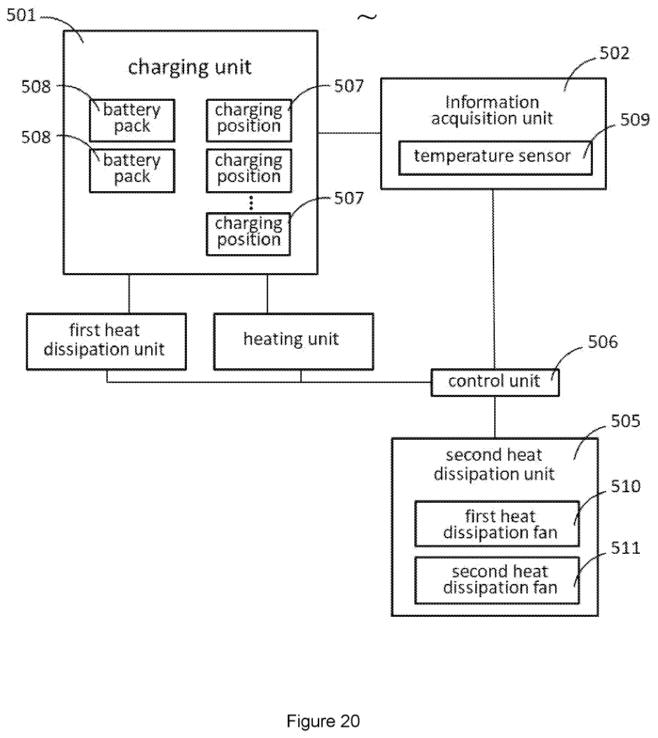

Please refer to FIG. 20, in another embodiment of the disclosure, the disclosure further provides a charger 50, the charger 50 including a charging unit 501, an information acquisition unit 502, a first heat dissipation unit 503, a heating unit 504, a second heat dissipation unit 505, and a control unit 506. The charging unit 501 includes a plurality of charging positions 507 for charging the battery pack 508 inserted into the charging position 507. The number of charging positions 507 can be set as required. The battery pack 508 may be a single battery or a battery pack including multiple single batteries. The information acquisition unit 502 is used to acquire a temperature of the battery pack 508 and a temperature of the charger 50. The information acquisition unit 502 performs handshake communication with the battery pack 508 to obtain the temperature of the battery pack 508. The information acquisition unit 502 further includes a temperature sensor 509 for detecting the temperature of the charger 50. The first heat dissipation unit 503 is used for heat dissipation of the battery pack 508. In this embodiment, the first heat dissipation unit 503 is a ventilation fan. When the first heat dissipation unit 503 works, the ventilation fan drives air to flow to the battery pack 508, so that the battery pack 508 exchanges heat with the air. The heating unit 504 is used to heat the battery pack 508 to increase the temperature of the battery pack 508. In this embodiment, the heating unit 504 is an electric heating wire. The second heat dissipation unit 505 is used for heat dissipation of the control unit 506 and the like of the charger 50. In this embodiment, the second heat dissipation unit 505 includes a first heat dissipation fan 510 located at the air inlet and a second heat dissipation fan 511 located at the air outlet. The control unit 506 controls the charging unit 501, the first heat dissipation unit 503, the heating unit 504, and the second heat dissipation unit 505 to work according to the temperature of the battery pack 508 and the temperature of the control unit 506. In this embodiment, the control unit 506 is a control circuit board integrated with various electronic components.

Please refer to FIG. 20, when the temperature of the battery pack 508 is greater than the first temperature threshold, the battery pack 508 is in a high temperature state, and at this time the battery pack 508 is not suitable for charging. If the battery pack 508 is charged at this time, the high temperature generated by the charging will damage the battery pack 508. In this embodiment, the first temperature threshold is, for example, between 35° C. to 60° C. Of course, it is understandable that the first temperature threshold can also be independently set by manufacturers or users according to a type of battery. When the battery pack 508 is in the high temperature state, the control unit 506 controls the charging unit 501 to stop working to prevent damage to the battery pack 508. At the same time, the operation of the first heat dissipation unit 503 is controlled to dissipate heat for the battery pack 508, thereby reducing the temperature of the battery pack 508. When the temperature of the battery pack 508 is less than a second temperature threshold, the battery pack 508 is in a low temperature state. Wherein, the second temperature threshold is less than the first temperature threshold. At this time, the battery pack 508 is also unsuitable for charging. If the battery pack 508 is charged at this time, the battery pack 508 will also be damaged. In this embodiment, the second temperature threshold is, for example, between −40° C. to 0° C. Of course, it is understandable that the second temperature threshold can also be independently set by manufacturers or users according to the type of battery. When the battery pack 508 is in a low temperature state, the control unit 506 controls the charging unit 501 to stop working to prevent damage to the battery pack 508. At the same time, the control unit 506 controls the heating unit 504 to work to heat the battery pack 508, thereby increasing the temperature of the battery pack 508. For example, when the charger 50 is used to charge the battery pack 508 in extremely cold regions such as Russia, the South Pole, the North Pole, etc., due to the extremely low ambient temperature, the battery pack 508 needs to be heated through the heating unit 504 to increase the temperature of the battery pack 508 at this time. Preferably, the ventilation fan of the first heat dissipation unit 503 works in cooperation with the heating unit 504. At this time, the ventilation fan drives external air to flow through the heating unit 504, and the heating unit 504 heats the air. Hot air flows into the inside of the battery pack 508 through heat dissipation holes on the battery pack 508, thereby heating the battery pack 508. With this arrangement, the charger 50 of the disclosure can charge the battery pack 508 in extremely cold regions, thereby expanding using range of the charger 50.

Please refer to FIG. 20, when the temperature of the battery pack 508 is between the first temperature threshold and the second temperature threshold, the control unit 506 controls the charging unit 501 to work, and controls the first heat dissipation unit 503 to work, so as to dissipate heat for the battery pack 508. Preferably, when the temperature of the battery pack 508 is greater than a third temperature threshold and less than the first temperature threshold, the control unit 506 controls the charging unit 501 to work at a first power/first current. Wherein, the third temperature threshold is greater than the second temperature threshold. In this embodiment, the third temperature threshold is, for example, between 25° C. to 30° C. Of course, it is understandable that the third temperature threshold can also be independently set by manufacturers or users according to the type of battery. When the temperature of the battery pack 508 is between the second temperature threshold and the third temperature threshold, the control unit 506 controls the charging unit 501 to work at a second power/second current. Wherein, the second power/second current is greater than the first power/first current. This arrangement allows the battery pack 508 to be charged with lower power/lower current when the temperature is higher. When the battery pack 508 returns to normal temperature, it is recharged with higher power/high current again. In another embodiment, when the charging unit 501 works at the first power/first current, the second heat dissipation unit 505 does not work. When the charging unit 501 works at the second power/second current, the second heat dissipation unit 505 works.

Please refer to FIG. 20, when the temperature of the charger 50 is greater than a first charging temperature, the control unit 506 controls the second heat dissipation unit 505 to work to dissipate heat for the charger 50. In this embodiment, the first charging temperature is between 30° C. and 40° C. Of course, it is understandable that the first charging temperature can also be set by manufacturers or users as required. Preferably, when the temperature of the charger 50 is greater than the first charging temperature and less than a second charging temperature, the control unit 506 controls any one of the first heat dissipation fan 510 and the second heat dissipation fan 511 to work to dissipate heat for the charger 50. At this time, the temperature of the charger 50 is not high, and one heat dissipation fan can meet the heat dissipation requirement of the charger 50, thereby saving electric energy. When the temperature of the charger 50 is greater than the second charging temperature, the control unit 506 controls the first heat dissipation fan 510 and the second heat dissipation fan 511 to work at the same time to enhance the heat dissipation efficiency. In this embodiment, the second charging temperature is, for example, between 50° C. and 60° C. Of course, it is understandable that the second charging temperature can also be set by manufacturers or users as required.

Please refer to FIG. 20, the charger 50 of the disclosure can automatically adjust working state according to the temperature of the battery pack 508, so as to avoid charging the battery pack 508 in a high temperature state or a low temperature state, thereby causing damage to the battery pack 508.

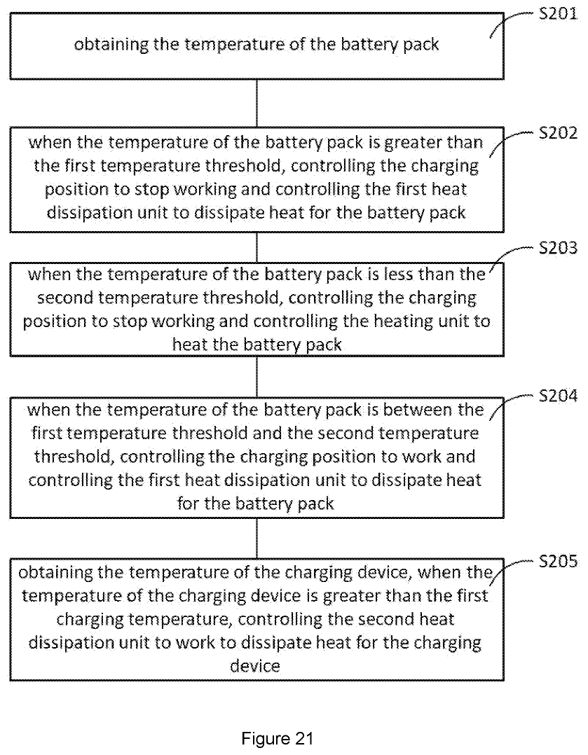

Please refer to FIG. 21. The disclosure also provides a control method of a charger for controlling the charger 50. The control method of charger includes following operations:

S201: obtaining a temperature of the battery pack,

S202: when the temperature of the battery pack is greater than a first temperature threshold, controlling a charging position to stop working and controlling a first heat dissipation unit to dissipate heat for the battery pack.

S203: when the temperature of the battery pack is less than a second temperature threshold, controlling the charging position to stop working and controlling the heating unit to heat the battery pack.

S204: when the temperature of the battery pack is between the first temperature threshold and the second temperature threshold, controlling the charging position to work and controlling the first heat dissipation unit to dissipate heat for the battery pack.

S205: obtaining a temperature of a charging device, when the temperature of the charging device is greater than the first charging temperature, controlling a second heat dissipation unit to work to dissipate heat for the charging device.

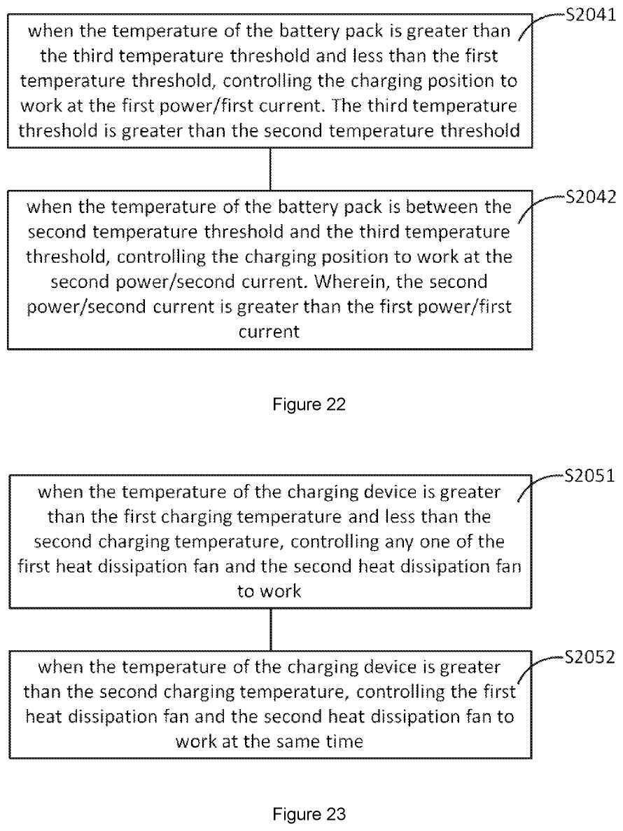

Please refer to FIG. 22, the operation S204 further includes following operations:

S2041: when the temperature of the battery pack is greater than the third temperature threshold and less than the first temperature threshold, controlling the charging position to work at a first power/first current. The third temperature threshold is greater than the second temperature threshold.

S2042: when the temperature of the battery pack is between the second temperature threshold and the third temperature threshold, controlling the charging position to work at a second power/second current. Wherein, the second power/second current is greater than the first power/first current.

Please refer to FIG. 23, the operation S205 further includes the following operations:

S2051: when the temperature of the charging device is greater than the first charging temperature and less than the second charging temperature, controlling any one of the first heat dissipation fan and the second heat dissipation fan to work.

S2052: when the temperature of the charging device is greater than the second charging temperature, controlling the first heat dissipation fan and the second heat dissipation fan to work at the same time.

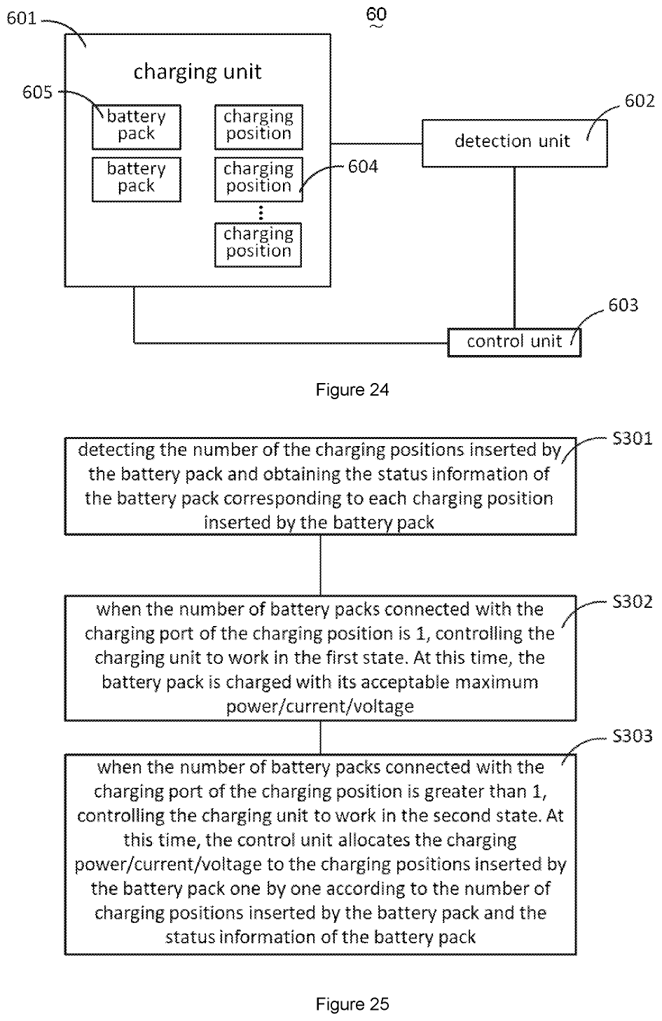

Please refer to FIG. 24. In another embodiment of the disclosure, the disclosure provides a charger 60, the charger 60 includes a charging unit 601, a detection unit 602, and a control unit 603. The charging unit 601 includes a plurality of charging positions 604. The charging position 604 is used to be matched with a battery pack 605 to charge the battery pack 605. The battery pack 605 may be a single battery or a battery pack including multiple single batteries. The detection unit 602 is used to detect the number of charging positions 604 inserted by the battery pack and obtain status information of the battery pack 605 corresponding to each charging position 604. The status information includes voltage, power, time T required to be fully charged of the battery pack 605, and so on. The control unit 603 controls the charging unit 601 to work according to the number of the charging positions 604 inserted by the battery pack and the corresponding status information of the battery pack 605. When the number of the battery packs 605 connected with a charging port of the charging station 604 is 1, the control unit 603 controls the charging unit 601 to work in a first state. At this time, the battery pack 605 is charged with its acceptable maximum power/maximum current/maximum voltage. When the number of the battery packs 605 connected to the charging port of the charging position 604 is greater than 1, the control unit 603 controls the charging unit 601 to work in a second state. At this time, the control unit 603 allocates charging power/current/voltage to the charging positions 604 inserted by the battery pack one by one according to the number of the charging positions 604 inserted by the battery pack and the corresponding status information of the battery pack 605. When the charging unit 601 is in the second state, a ratio between the charging power/current/voltage received by the battery packs 605 corresponding to the charging positions 604 is the same as a ratio of the nominal capacity of the battery packs 605 corresponding to the charging positions 604.

Please refer to FIG. 24, when the nominal capacities of the battery packs 605 in the charging positions 604 are the same, the control unit 603 determines charging priority level according to voltage/power level of the battery pack 605 corresponding to each charging position 604. For example, if nominal capacities of a battery pack A and a battery pack B are the same and voltage/power of the battery pack A is less than the voltage/power of the battery pack B, the charging priority of the charging position 604 inserted by the battery pack A is higher than the charging priority of the charging position 604 inserted by the battery pack B. If the voltage/power difference between the battery pack A and the battery pack B is less than a preset threshold, the charging priority level of the charging position 604 inserted by the battery pack A and the charging priority level of the charging position 604 inserted by the battery pack B are the same. The preset threshold can be set by users as needed. The control unit 603 sequentially controls the corresponding charging positions 604 to work according to the order of the charging priority levels. When the voltage difference between the battery pack 605 of the currently working charging position 604 and the battery pack 605 of the charging position 604 corresponding to the next charging priority level is less than a first voltage threshold, the control unit 603 controls the charging position 604 corresponding to the next charging priority level to work with the currently working charging position 604 together, and so on, until all the charging positions 604 inserted by the battery pack 605 are in a working state. The first voltage threshold can be set as needed. Of course, it can be understood that in other embodiments, it can also be set to: when the power difference between the battery pack 605 of the currently working charging position 604 and the battery pack 605 of the charging position 604 corresponding to the next charging priority level is less than a first power threshold, the control unit 603 controls the charging position 604 corresponding to the next charging priority level to work with the currently working charging position 604 together, and so on, until all the charging positions 604 inserted by the battery pack 605 are in a working state. When the number of currently working charging positions 604 is N (N>1), the charging power/current/voltage received by each working charging position 604 is 1/N of a maximum output power or a maximum output current or a maximum output voltage of the charger 60.

Please refer to FIG. 24. The charger 60 of the disclosure can allocate charging power/current/voltage to the corresponding charging position 604 of each battery pack 605 according to the number of the charging positions 604 inserted by the battery pack and the status information of the corresponding battery pack 605, thereby improving charging efficiency of the charger 60 and shortening users' waiting time.

Please refer to FIG. 25. The disclosure further provides a control method of charger for controlling the charger 60. The control method of charger includes the following operations:

S301: detecting a number of charging positions inserted by the battery pack and obtaining status information of the battery pack corresponding to each charging position inserted by the battery pack. The status information includes voltage, power, and time T required to be fully charged of the battery pack, and so on.

S302: when the number of battery packs connected with the charging port of the charging position is 1, controlling the charging unit to work in a first state. At this time, the battery pack is charged with its acceptable maximum power/current/voltage.

S303: when the number of battery packs connected with the charging port of the charging position is greater than 1, controlling the charging unit to work in a second state. At this time, the control unit allocates the charging power/current/voltage to the charging positions inserted by the battery pack one by one according to the number of charging positions inserted by the battery pack and the status information of the battery pack.

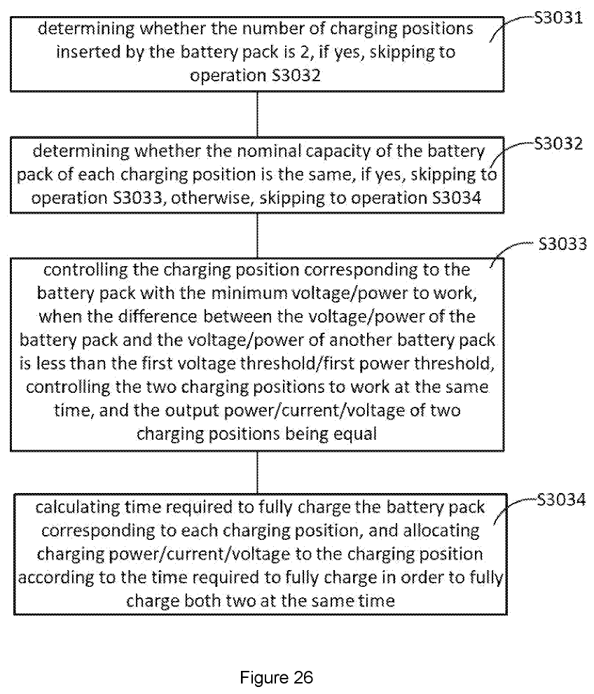

Please refer to FIG. 26, the operation S303 further includes the following operations:

S3031: determining whether the number of charging positions inserted by the battery pack is 2, if yes, skipping to operation S3032.

S3032: determining whether the nominal capacity of the battery pack of each charging position is the same, if yes, skipping to operation S3033, otherwise, skipping to operation S3034.

S3033: controlling the charging position corresponding to the battery pack with the minimum voltage/power to work, when the voltage difference or power difference between the battery pack and another battery pack is less than the first voltage threshold/first power threshold, controlling the two charging positions to work at the same time, and output power/current/voltage of two charging positions being equal.

S3034: calculating time required to fully charge the battery pack corresponding to each charging position, and allocating charging power/current/voltage to the charging position according to the time required to fully charge in order to fully charge both two at the same time.

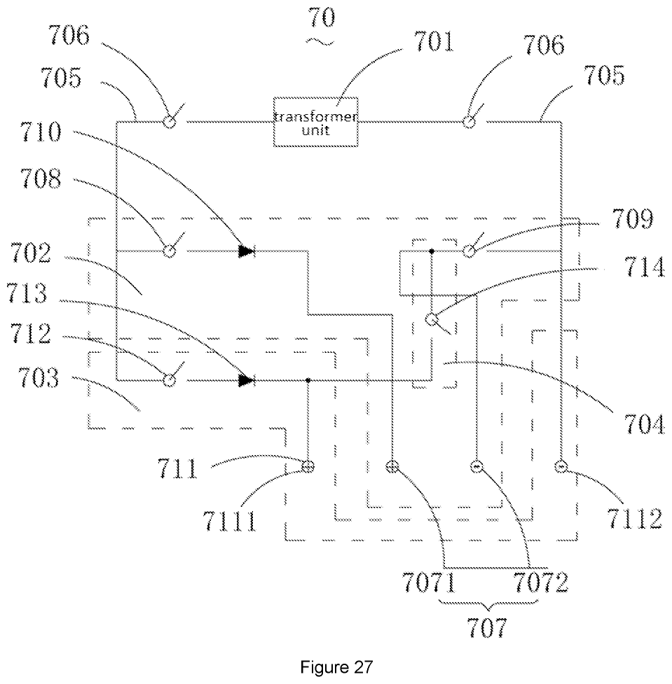

Please refer to FIG. 27. In another embodiment of the disclosure, the disclosure provides a charger 70 for charging a single-voltage battery pack or a multi-voltage battery pack inserted into the charging port of the charger 70. The charger 70 includes a transformer unit 701, a first charging unit 702, a second charging unit 703, a switching unit 704, and a control unit (not shown).

Please refer to FIG. 27, the transformer unit 701 is used to be connected with an external power source to obtain power and convert the power into a required voltage. Main circuits 705 are arranged on both sides of the transformer unit 701. One end of the main circuit 705 is connected to the transformer unit 701, and the other end thereof is connected to the first charging unit 702 and the second charging unit 703. A sixth switch 706 is arranged on the main circuit 705 to control connection and disconnection between the transformer unit 701 and the first charging unit 702 and the second charging unit 703, thereby improving safety performance of the charger 70.

Please refer to FIG. 27, the first charging unit 702 is connected to the main circuit 705, and includes a first terminal group 707 for connecting with a first battery cell group of the battery pack, a first switch 708 and a second switch 709 located on both sides of the first terminal group 707, and an isolation diode 710. The first switch 708, the isolation diode 710, the first terminal group 707, and the second switch 709 are sequentially connected to the main circuit 705. The first terminal group 707 includes a first positive electrode 7071 and a first negative electrode 7072. The isolation diode 710 is located between the first switch 708 and the first positive electrode 7071, which means that the isolation diode 710 is located on a side of the first terminal group 707 away from the negative electrode. Of course, in other embodiments, the isolation diode 710 can also be arranged on a side of the first terminal group 707 away from the positive electrode. The second charging unit 703 is connected with the transformer unit 701 and includes a second terminal group 711 for connecting with a second battery cell group of the battery pack, a third switch 712 located on one side of the second terminal group 711, and an isolation diode 713. The third switch 712, the isolation diode 713, and the second terminal group 711 are sequentially connected to the main circuit 705. The second terminal group 711 includes a second positive electrode 7111 and a second negative electrode 7112. The isolation diode 713 is located between the third switch 712 and the second positive electrode 7111, which means that the isolation diode 713 is located on one side of the second terminal group 711 away from the negative electrode. In this embodiment, the third switch 712 is located on the side of the second terminal group 711 away from the negative electrode, but in other embodiments, the third switch 712 may also be arranged on one side of the second terminal group 711 away from the positive electrode. The first terminal group 707 and the second terminal group 711 together constitute a charging port or part of a charging port of the charger 70. The isolation diode 710 and the isolation diode 713 are used to limit flow direction of current to prevent the battery pack from being short-circuited during state switching of the first switch 708, the second switch 709, the third switch 712, and the switching unit 704, thereby preventing damage to the battery pack, the switch, and the switching unit 704. The first switch 708, the second switch 709, the third switch 712, and the sixth switch 706 may be magnetic relays, MOS transistors, or insulated gate bipolar transistors.

Please refer to FIG. 27, the switching unit 704 includes a first switching switch 714. One end of the first switching switch 714 is connected to the first negative electrode 7072 of the first terminal group 707, and the other end thereof is connected to the second positive electrode 7111 of the second terminal group 711. Of course, in other embodiments, it can also be arranged such that one end of the first switching switch 714 is connected to the first positive electrode 7071 of the first terminal group 707, and the other end thereof is connected to the second negative electrode 7112 of the second terminal group 711. The control unit communicates with the battery pack to obtain internal information of the battery pack inserted into the charging port, and controls the first switch 708, the second switch 709, and the third switch 712 to work according to the internal information, so that the first charging unit 702 and the second charging unit 703 works in series or in parallel. The internal information includes type information, charging requirements, rated charging voltage information, and rated charging current information of the battery pack. The type information is used to indicate that the battery pack is a single-voltage battery pack, or a multi-voltage battery pack, etc. The charging requirement is used to indicate that the multi-voltage battery pack needs to charge a plurality of battery cell groups in series or in parallel. The control unit controls the voltage output by the transformer unit 701 to be the rated charging voltage according to the obtained rated charging voltage information.

Please refer to FIG. 27, the main circuit 705 may also be provided with a main circuit current detection component (not shown). When a current detected by the main circuit current detection component is greater than the rated charging current, the control unit controls the charger 70 to stop working or limit the current. Further, the first charging unit 702 is further provided with a first current detection component, and the second charging unit 703 is further provided with a second current detection component. When the current detected by the first current detection component or the second current detection component is greater than a maximum current allowed by the first charging unit 702 or the second charging unit 703, the control unit controls the first charging unit 702 or the second charging unit 703 to stop working or limit the current.

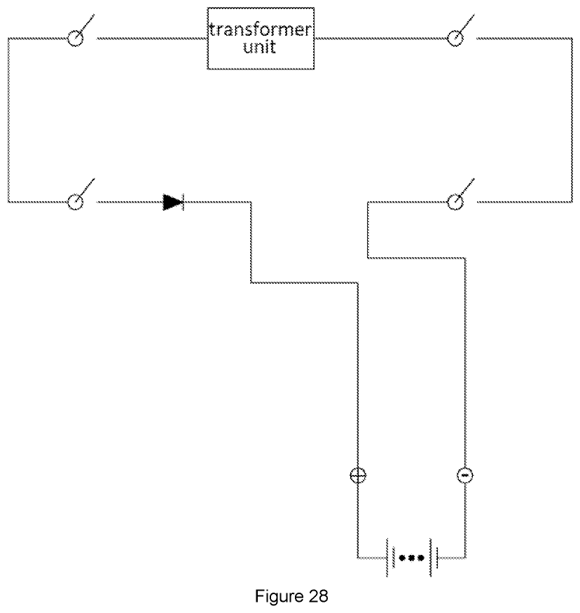

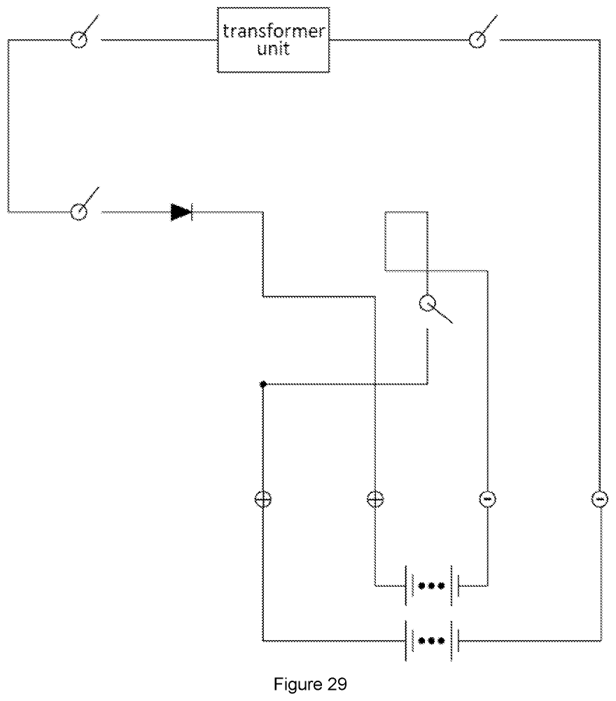

Please refer to FIG. 27, when using the charger 70, first insert the battery pack into the charging port. The control unit communicates with the battery pack to obtain internal information of the battery pack. When detecting that the inserted battery pack is a single-voltage battery pack, the control unit controls the transformer unit 701 to output the rated charging voltage of the battery pack, and then controls the sixth switch 706, the first switch 708, and the second switch 709 to be closed, and controls the first switching switch 714 and a third switch 712 to be open, so that the first charging unit 702 charges the battery pack. At this time, an actual working circuit can be simplified as shown in FIG. 28. When detecting that the inserted battery pack is a multi-voltage battery pack, if the battery pack needs to be charged in series, the control unit controls the sixth switch 706, the first switch 708, and the first switch 714 to be closed, and controls the second switch 709 and the third switch 712 to be open, so that the first charging unit 702 and the second charging unit 703 are connected in series. At this time, the actual working circuit is shown in FIG. 29. If the battery pack needs to be charged in parallel, the control unit controls the sixth switch 706, the first switch 708, the second switch 709, and the third switch 712 to be closed, and controls the first switch 714 be open, so that the first charging unit 702 and the second charging units 703 are connected in parallel, and the actual working circuit is shown in FIG. 30 at this time.

Please refer to FIG. 27, the charger 70 of the disclosure can not only charge single-voltage battery packs with different voltages, but also charge multi-voltage battery packs with different voltages, and can automatically select a series or parallel charging mode according to charging requirements of the multi-voltage battery packs, thereby reducing users' maintenance difficulty and cost, and effectively avoiding problems of damage to the charger and battery pack due to incorrect use of the charger.

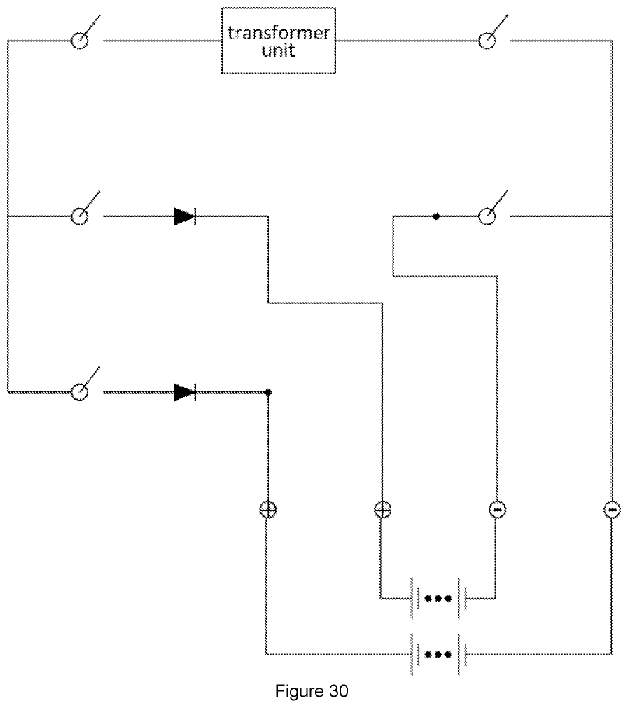

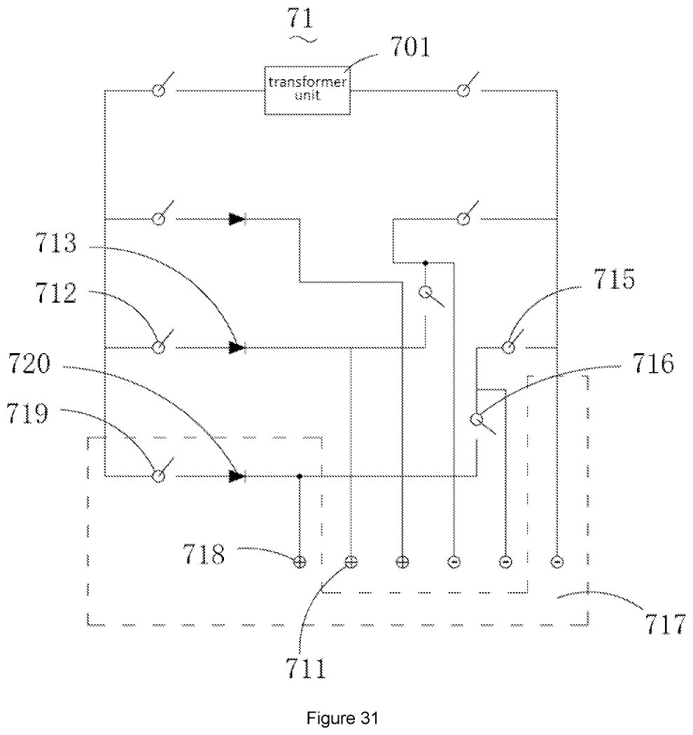

Please refer to FIG. 31. The disclosure provides another charger 71. The structure of the charger 71 and the charger 70 are substantially the same, and the difference is that the charger 71 further includes a third charging unit 717. The third charging unit 717 is connected with the transformer unit 701 and includes a third terminal group 718 for connecting with a third battery cell group of the battery pack, a fifth switch 719 located on one side of the third terminal group 718, and an isolation diode 720. The second charging unit 703 is further provided with a fourth switch 715 located on a side of the second terminal group 711 away from the third switch 712. The switching unit 704 further includes a second switching switch 716. One end of the second switching switch 716 is connected to a negative electrode of the second terminal group 711, and the other end thereof is connected to a positive electrode of the third terminal group 718. Of course, it is understandable that in practice, the number of charging units can be set as required.

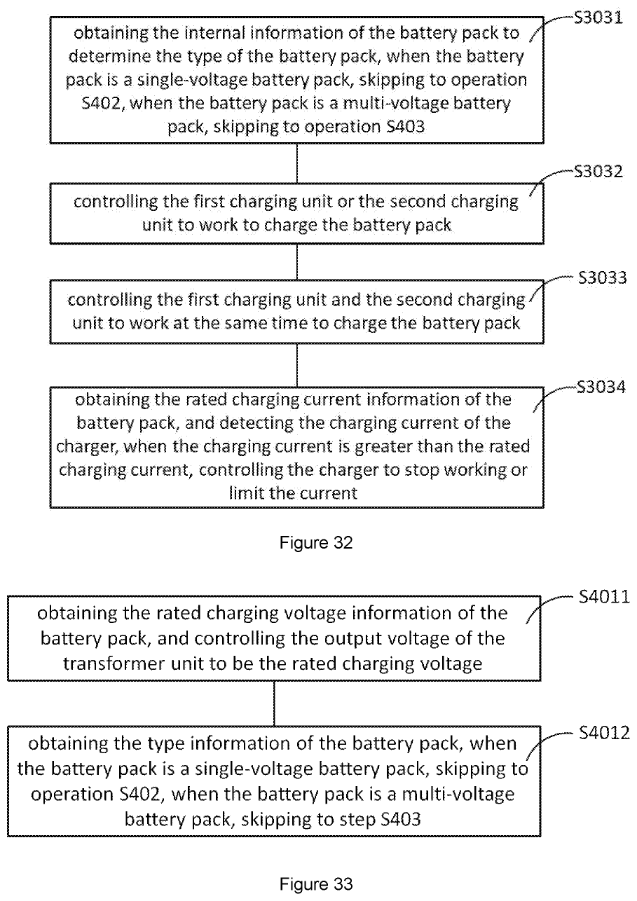

Please refer to FIG. 32. The disclosure further provides a control method of a charger, the control method includes the following operations:

S401: obtaining internal information of a battery pack to determine a type of the battery pack, when the battery pack is a single-voltage battery pack, skipping to operation S402, when the battery pack is a multi-voltage battery pack, skipping to operation S403.

S402: controlling the first charging unit or the second charging unit to work to charge the battery pack.

S403: controlling the first charging unit and the second charging unit to work at the same time to charge the battery pack.

S404: obtaining rated charging current information of the battery pack, and detecting charging current of the charger, when the charging current is greater than the rated charging current, controlling the charger to stop working or limit the current.

Please refer to FIG. 33. Preferably, the operation S401 further includes the following operations:

S4011: obtaining rated charging voltage information of the battery pack, and controlling output voltage of the transformer unit to be the rated charging voltage.

S4012: obtaining the type information of the battery pack, when the battery pack is a single-voltage battery pack, skipping to operation S402, when the battery pack is a multi-voltage battery pack, skipping to step S403.

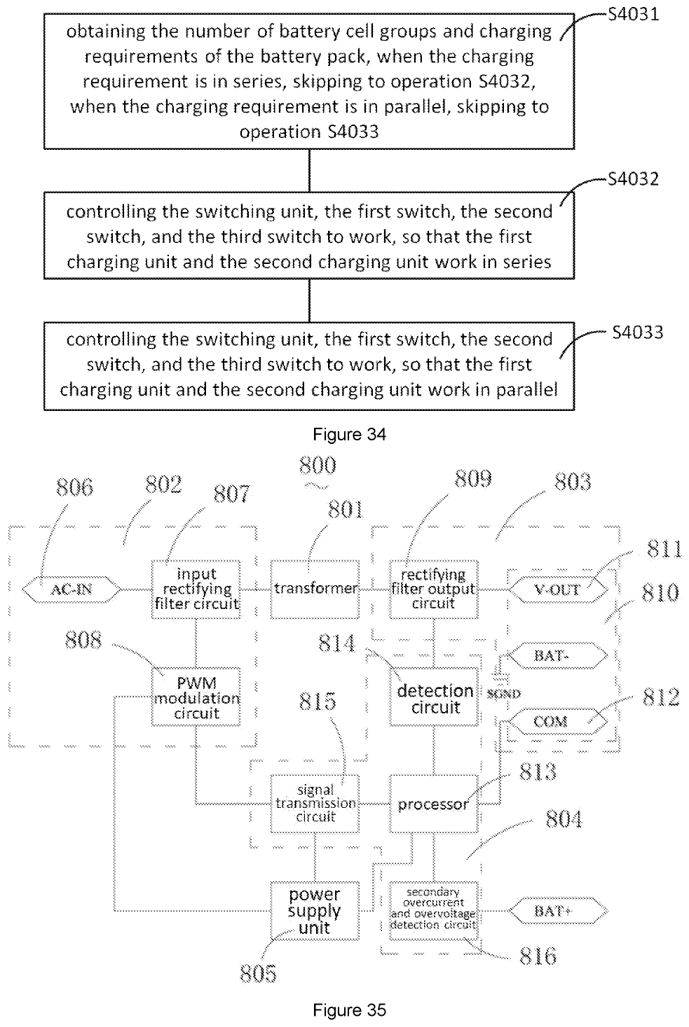

Please refer to FIG. 34. Preferably, the operation S403 further includes the following operations:

S4031: obtaining a number of battery cell groups and charging requirements of the battery pack, when the charging requirement is charging in series, skipping to operation S4032, when the charging requirement is charging in parallel, skipping to operation S4033.

S4032: controlling the switching unit, the first switch, the second switch, and the third switch to work, so that the first charging unit and the second charging unit work in series.

S4033: controlling the switching unit, the first switch, the second switch, and the third switch to work, so that the first charging unit and the second charging unit work in parallel.

Please refer to FIG. 35, the disclosure provides a transformer module 800, transformer module 800 includes a transformer 801, a primary circuit 802 connected with the transformer 801, a secondary circuit 803 connected with the transformer 801, a control unit 804, and a power supply unit 805.

Please refer to FIG. 35, the transformer 801 includes an input part (not shown) and an output part (not shown) corresponding to the input part. Preferably, the transformer 801 is an isolation transformer. The primary circuit 802 is connected with the input unit, and includes an input port 806, an input rectifying filter circuit 807, and a PWM modulation circuit 808. The input port 806 is used to obtain external power, such as alternating current. The input rectifying filter circuit 807 is used to rectify and filter power obtained by the input port 806 and output the power to the input part. The PWM modulation circuit 808 is used to modulate the input rectifying filter circuit 807, and achieves the purpose of controlling output voltage and output current of the primary circuit 802 through adjusting period of the PWM and a duty ratio of the PWM. The secondary circuit 803 is connected with the output part, and includes a rectifying filter output circuit 809 and an output port 810. The rectifying filter output circuit 809 is used to rectify and filter power output from the output part of the transformer 801 and transmit it to the output port 810. The output port 810 is used to output power to a load. The output port 810 includes a conductive terminal 811 for outputting power and a communication terminal 812.

Please refer to FIG. 35, the control unit 804 communicates with a load to obtain voltage information of the load, and controls the PWM modulation circuit 808 to work according to the voltage information, so that the voltage output by the output port 810 matches the load. Further, the control unit 804 communicates with the load to obtain temperature information of the load, and controls PWM modulation circuit 808 to work according to the temperature information, so that the current output by the output port 810 matches the load.

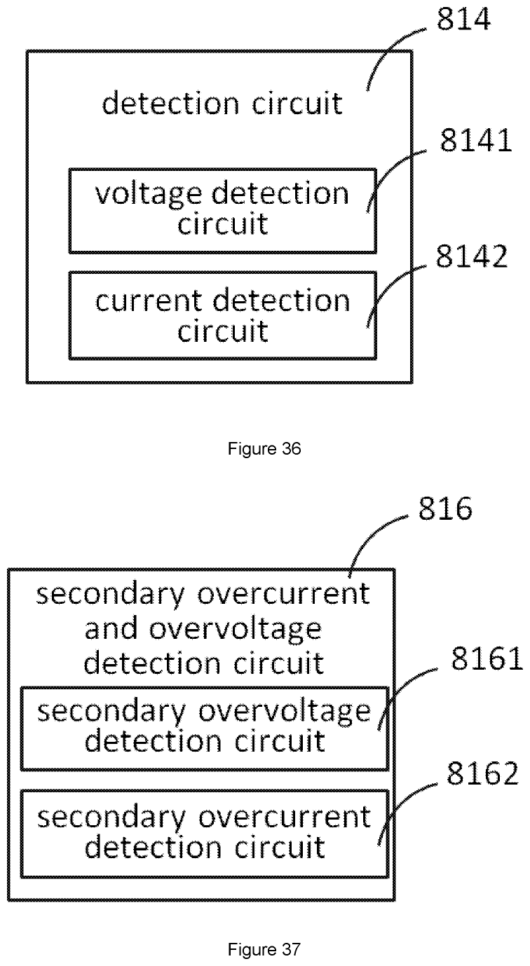

Please refer to FIG. 35. Specifically, the control unit 804 includes a processor 813, a detection circuit 814, a signal transmission circuit 815, and a secondary overcurrent and overvoltage detection circuit 816. In this embodiment, the processor 813 is a micro control unit (MCU), and communicates with the load through the communication terminal 812. Please refer to FIG. 36, the detection circuit 814 includes a voltage detection circuit 8141 for detecting output voltage of the output port 810 and a current detection circuit 8142 for detecting output current of the output port 810. The processor 813 sends out a control signal according to the voltage information and the temperature information of the load, the output voltage of the output port 810, and the output current of the output port 810, and transmits the control signal to the PWM modulation circuit 808 through the signal transmission circuit. The signal transmission circuit 815 is used to transmit a signal sent by the processor 813 to the PWM modulation circuit 808. In order to prevent current and voltage of the processor 813 from interfering with the PWM modulation circuit 808, preferably, the signal transmission circuit 815 is an isolation signal transmission circuit, such as an optical coupler. Please refer to FIG. 37, the secondary overcurrent and overvoltage detection circuit 816 includes a secondary overvoltage detection circuit 8161 that detects the voltage of the load and a secondary overcurrent detection circuit 8162 that detects the current of the load. Further, the processor 813 communicates with the load to obtain a maximum voltage and a maximum current that the load can withstand. When the secondary overvoltage detection circuit 8161 detects that the voltage of the load is greater than the maximum voltage, the secondary overvoltage detection circuit 8161 controls the secondary circuit 803 to stop outputting power. When the secondary overcurrent detection circuit 8162 detects that the current of the load is greater than the maximum current, the secondary overcurrent detection circuit 8162 controls the secondary circuit 803 to stop outputting power.

Please refer to FIG. 35, the power supply unit 805 is used for supplying power to the PWM modulation circuit 808 and the control unit 804. Preferably, the power sources connected to the power supply unit 805 and the input port 806 are independent of each other, which means that the PWM modulation circuit 808, the control unit 804, and the input port 806 do not share a power source. Such an arrangement can enable the transformer module 800 to work more reliably and stably, and effectively improve the overall stability of the transformer module 800. Secondly, due to use of the independent power supply unit 805, all circuits of main power may be completely shut down and stop working in the case of standby, so as to reduce power consumption and increase safety performance of the product. In other embodiments, the power supply unit 805 may also be arranged to be connected with the input part of the transformer 801 to obtain power. In another embodiment, the power supply unit 805 may also be arranged to be connected with the input rectifying filter circuit 807 to obtain power.

Please refer to FIG. 35, the transformer module 800 of the disclosure can automatically control the secondary circuit 803 to output a voltage matching the load according to the voltage information of the load, so that the transformer module 800 has a wider application range and reduces users' use and maintenance costs.

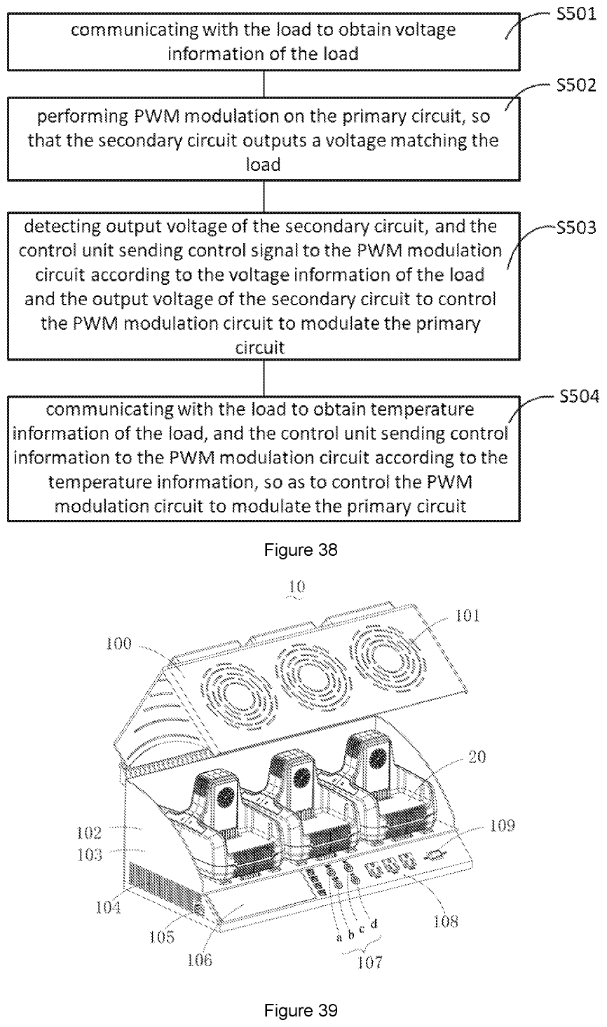

Please refer to FIG. 38. The disclosure also provides a control method of variable voltage, the control method includes the following operations:

S501: communicating with a load to obtain voltage information of the load.

S502: performing PWM modulation on a primary circuit, so that a secondary circuit outputs a voltage matching the load.

S503: detecting output voltage of the secondary circuit, and a control unit sending a control signal to the PWM modulation circuit according to the voltage information of the load and the output voltage of the secondary circuit to control the PWM modulation circuit to modulate the primary circuit.

S504: communicating with the load to obtain temperature information of the load, and the control unit sending control information to the PWM modulation circuit according to the temperature information, so as to control the PWM modulation circuit to modulate the primary circuit.

Please refer to FIG. 38, the operation S504 further includes: detecting output current of the secondary circuit and the control unit sending control information to the PWM modulation circuit according to the temperature information of the load and the output current of the secondary circuit to control the PWM modulation circuit to modulate the primary circuit.

Please refer to FIG. 35, the power input of the charger is arranged on the side wall of the housing to obtain external power, such as alternating current. The transformer module 800 is housed in the housing. The input port 806 of the transformer module 800 is electrically connected to the power input, so that the transformer module 800 can obtain external power through the power input. When the charger is used to charge the battery pack, the battery pack is the load. When a temperature of the battery pack is higher than a charging temperature threshold, the control unit 804 sends a control signal to the PWM modulation circuit 808, and the PWM modulation circuit 808 modulates the primary circuit 802, so that the output port 810 outputs a first current. When the temperature of the battery pack is lower than the charging temperature threshold, the control unit 804 sends a control signal to the PWM modulation circuit 808, and the PWM modulation circuit 808 modulates the primary circuit 802, so that the output port 810 outputs a second current. Wherein, the second current is greater than the first current.

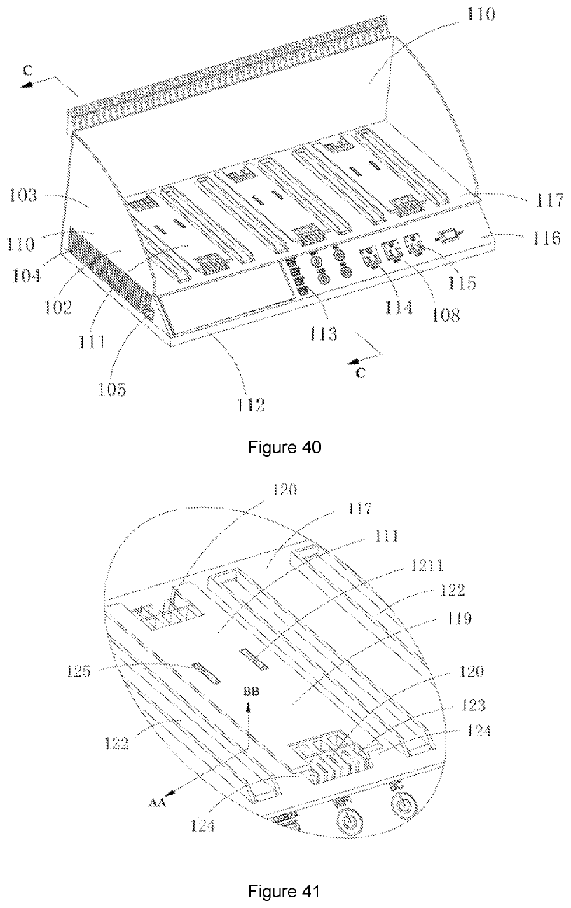

Please refer to FIG. 39 and FIG. 40. The disclosure provides a charging device 10 for charging a battery pack, and at the same time, the charging device 10 can obtain power from the battery pack and invert the power into alternating current to output for the user to use. The charging device 10 includes a housing 102, a charging part 111 housed in the housing 102, an output unit 108, an inverter unit (not shown), a control unit (not shown), and a charger 20 matched with the charging part 111.

Please refer to FIG. 39 and FIG. 40, the housing 102 includes a base body 103 and a top cover 100 pivotally mounted on the base body 103. The base body 103 includes a bottom wall 112, a top wall 117 arranged opposite to the bottom wall 112, a side wall 110 perpendicular to the bottom wall 112, and a control board 116 located between the bottom wall 112 and the top wall 117. The bottom wall 112, the top wall 117, the side wall 110, and the control board 116 jointly form a receiving cavity for housing at least one circuit board. The circuit board is provided with an inverter unit, a control unit, and so on. The side wall 110 is provided with a ventilation hole 104 and a power input 105. The ventilation hole 104 communicates with the receiving cavity so as to dissipate heat for components in the receiving cavity. The power input 105 is used to connect with an external power source to obtain external power, such as mains supply. The control board 116 is inclined to facilitate users' operations. A power switch 109, a control switch 107, and a display unit 106 are arranged on the control board 116. The power switch 109 is used to control connection and disconnection of the charging device 10 and the power input 105. When the power input 105 is connected with the mains supply, if the power switch 109 is turned on, the charging device 10 can obtain the mains supply through the power input 105. If the power switch 109 is turned off, the charging device 10 cannot obtain mains supply through the power input 105. The control switch 107 includes, for example, a WIFI switch a, a USB switch b, a BC switch c, and an AC switch d. The WIFI switch a is used to turn on WIFI network, so as to connect with the network through WIFI, exchange data with the cloud. Further, data exchange includes data upload, data download, software update, and so on. When the USB switch b is turned on, a third output interface 113 can output direct current to the outside. When the BC switch c is turned on, the display unit 106 displays power information of the battery pack. When the AC switch d is turned on, the first output interface 114 can output alternating current to the outside. The display unit 106 is used to display information such as charging and discharging of the battery pack, status information of the control switch 107, and so on. The top cover 100 is pivotally mounted on the base body 103. The top cover 100 is matched with the base body 103 to form a cavity for housing the charging part 111 and the charger 20. A plurality of ventilation holes 101 are arranged on the top cover 100 to dissipate heat for the charging part 111, the charger 20, etc., located in the cavity.

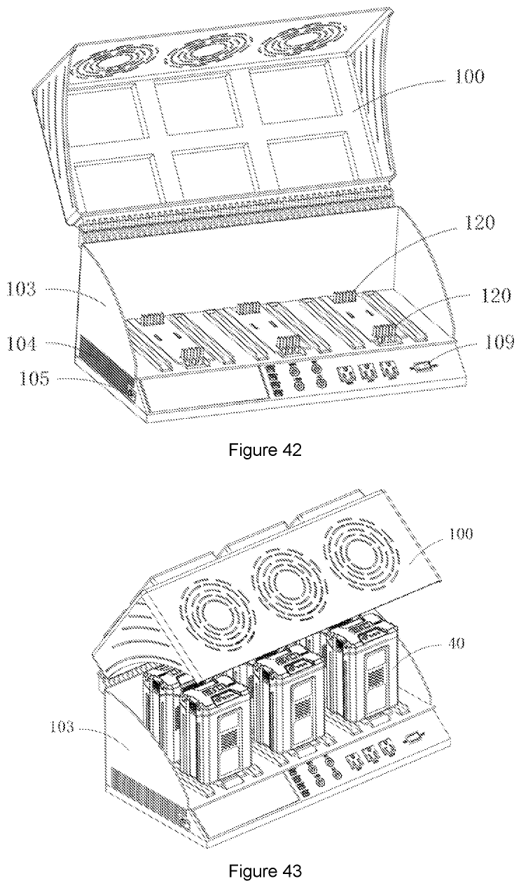

Please refer to FIG. 39, FIG. 40 and FIG. 41, the charging part 111 is arranged on the top wall 117. In this embodiment, the number of charging parts 111 is three, for example. However, in actual applications, the number of charging parts 111 can be set as needed. The charging part 111 includes a seat 119, first connecting interfaces 120 and a second connecting interface 1211 arranged on the seat 119, and a guiding groove 122 arranged on the top wall 117. The seat 119 is used to carry the charger 20 or the battery pack, and is provided with a receiving groove 123 for housing the first connecting interfaces 120, and first sliding rails 124 is arranged on the edge of the seat 119. The first connecting interfaces 120 are used for connecting with the battery pack to charge the battery pack or obtain power from the battery pack. When the first connecting interfaces 120 need to be connected with the battery pack, the first connecting interfaces 120 are set to protrude from the receiving groove 123 and be perpendicular to the seat 119. When the first connecting interfaces 120 are not connected with the battery pack, the first connecting interfaces 120 are set to be housed in the receiving groove 123. In this embodiment, the first connecting interfaces 120 are pivotally mounted in the receiving groove 123. Please refer to FIG. 42 and FIG. 43. When the first connecting interfaces 120 need to be connected with the battery pack, it is only necessary to rotate the first connecting interfaces 120. At this time, the first connecting interfaces 120 protrude from the receiving groove 123 and are perpendicular to the seat 119. When the first connecting interfaces 120 are not connected with the battery pack, it is only necessary to reverse the first connecting interfaces 120. At this time, the first connecting interfaces 120 are housed in the receiving groove 123 and are parallel to the seat 119. In this embodiment, the number of the first connecting interfaces 120 is two, and they are located at front and rear ends of the seat 119 respectively. In this embodiment, the battery pack is set to be vertically inserted into the first connecting interfaces 120, but in other embodiments, the battery pack and the first connecting interfaces 120 may also be set to be horizontally inserted and connected.

Please refer to FIG. 39 and FIG. 40, the output unit 108 is arranged on the control board 116 for outputting power to the outside. The output unit 108 includes a first output interface 114, a second output interface 115, and a third output interface 113. The first output interface 114 and the second output interface 115 are used to output alternating current, and the third output interface 113 is used to output direct current. In this embodiment, the first output interface 114 is set to output, for example, 120V alternating current, the second output interface 115 is set to output, for example, 220V alternating current, and the third output interface 113 is set to output, for example, 5V direct current. Of course, in other embodiments, output voltages of the first output interface 114, the second output interface 115, and the third output interface 113 can be set as required. In this embodiment, the third output interface 113 includes a USB 2.0 interface, a USB 3.0 interface, a Micro USB interface, and a Type-C interface. The inverter unit is used to invert the power obtained from the battery pack by the first connecting interfaces 120 into alternating current and output the alternating current through the output unit 108, or output the received alternating current to the output unit 108 after adjustment.

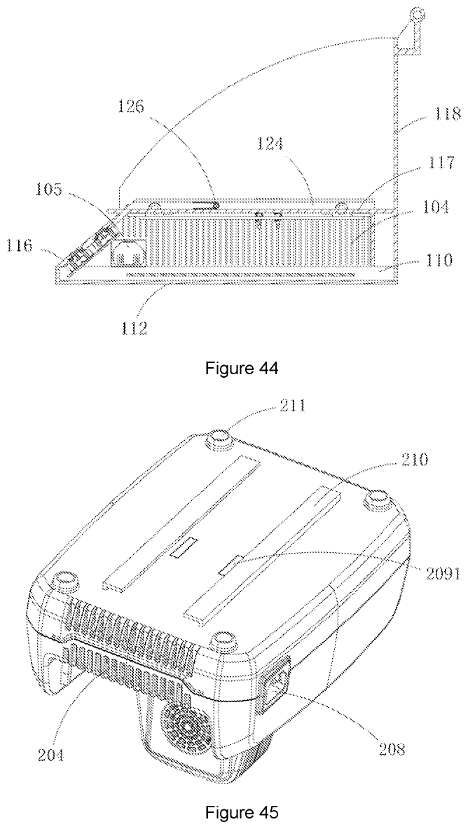

Please refer to FIG. 1, FIG. 41, and FIG. 45 together. The charging device 10 can charge the battery pack through the charger 20, and the charger 20 can be used as a separate charging device to charge the battery pack. The charger 20 includes a base 200 and a supporting part 201 arranged on the base 200. A plurality of charging positions 202 matched with the battery pack are arranged on the top of the base 200. The charging positions 202 are distributed around the supporting part 201. In this embodiment, the number of charging positions 202 is, for example, two. The bottom of the base 200 is provided with a second connecting port 2091 matched with the second connecting interface 1211, second sliding rails 210 matched with the first sliding rails 124, and supporting feet 211. The second connecting port 2091 is connected with the second connecting interface 1211 so that the charger 20 obtains power of the charging device 10 and charges the battery pack inserted into the charger 20. In this embodiment, the second connecting interface 1211 includes a first conductive terminal 125 and a first elastic component (not shown) matched with the first conductive terminal 125. The second connecting port 2091 is a second conductive terminal matched with the first conductive terminal 125. When the charger 20 is inserted into the charging part 111, the second conductive terminal abuts the first conductive terminal 125, and the first elastic component is elastically deformed under the action of the first conductive terminal 125 at this time. When the charger 20 is separated from the charging part 111, the first conductive terminal 125 is reset under the action of the first elastic component. With this arrangement, the first conductive terminal 125 can apply a certain force to the second conductive terminal, thereby ensuring sufficient contact between the first conductive terminal 125 and the second conductive terminal and avoiding poor contact. The second sliding rails 210 are matched with the first sliding rails 124 to guide the charger 20 to slide into the charging part 111. Preferably, please refer to FIG. 44, the first sliding rails 124 are further provided with a micro switch 126. When the second sliding rails 210 are slidably inserted into the first sliding rails 124, the second sliding rails 210 abuts the micro switch 126, and at this time, the control unit controls the charging device 10 to supply power to the second connecting interface 1211. When the second sliding rails 210 withdraw from the first sliding rails 124, the micro switch 126 is reset. At this time, the control unit controls the charging device 10 to stop supplying power to the second connecting interface 1211. This arrangement enables the second connecting interface 1211 to be energized only when the charger 20 is inserted into the charging part 111, thereby effectively enhancing safety performance of the charging device 10 and avoiding electric shock caused by users' accidentally touching the second connecting interface 1211. In this embodiment, the first sliding rails 124 are guiding grooves, and the second sliding rails 210 are guiding rails matched with the guiding grooves. Preferably, the opening direction AA of the guiding grooves is parallel to the seat 119, so that the guiding grooves can limit the charger 20 in the direction BB perpendicular to the seat 119. The supporting feet 211 are matched with guiding grooves 122 and slides along the guide grooves 122. Preferably, in order to balance the charger 20, a height of the supporting feet 211 is greater than a height of the second sliding rails 210.

Please refer to FIG. 39 to FIG. 43. When the power input 105 is connected to the mains supply, first the power switch 109 is turned on, and then the battery pack is inserted into the first connecting interface 120. At this time, the control unit controls the first connecting interface 120 to charge battery pack. If the BC switch c is pressed, the display unit 106 displays the power information of the battery pack. If the charger 20 with the battery pack inserted is inserted into the charging part 111, the control unit controls the charging device 10 to supply power to the charger 20 through the second connecting interface 1211 and the second connecting port 2091, thereby charging the battery pack inserted into the charger 20. At this time, if the BC switch c is pressed, the display unit 106 displays the power information of the battery pack. When the power input 105 is disconnected from the mains supply, the control unit controls the first connecting interface 120 to obtain power from the battery pack and invert the power to alternating current through the inverter unit, and then output power to the outside through the output unit 108. When the AC switch d is pressed, the first output interface 114 can output, for example, 120V alternating current to the outside, and the second output interface 115 can output, for example, 220V alternating current to the outside. When the USB switch b is pressed, the third output interface 113 can output, for example, 5V direct current to the outside.

Please refer to FIG. 45, the charger 20 is provided with a power input interface 208 to facilitate the charger 20 to be directly connected to the mains supply and charge the battery pack inserted into the charger 20.

Please refer to FIG. 39 through FIG. 45, the charging device 10 can not only charge multiple battery packs at the same time, which shortens users' waiting time and improves the charging efficiency, but also can invert the power in the battery packs into alternating current, thereby solving the problem that users need emergency power supplies outdoors. Secondly, since the charger 20 is detachably matched with the charging part 111, users can easily take out the charger 20 and the battery pack inserted into the charger 20 as a whole, so that the battery pack can be charged by the charger alone in extreme cases.

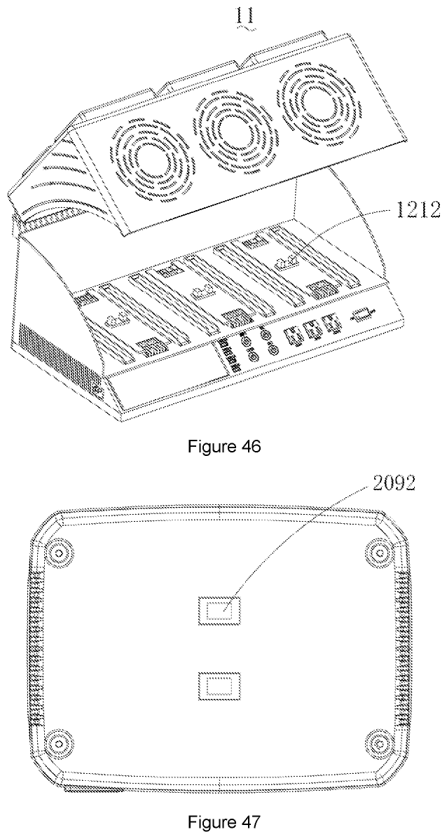

Please refer to FIG. 46 and FIG. 47, the disclosure further provides a charging device 11. The structure of the charging device 11 is substantially the same as that of the charging device 10, and the difference is that a second connecting interface 1212 is a male socket, and a second connecting port 2092 is a female socket.

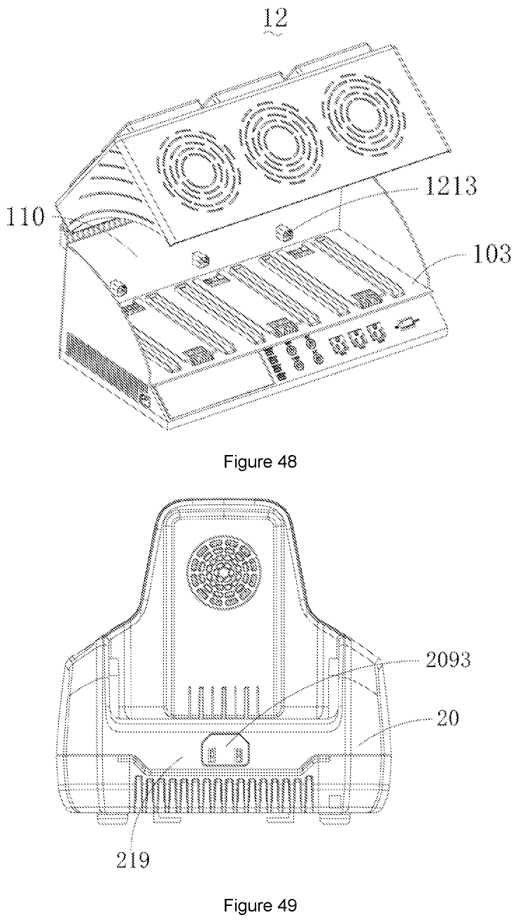

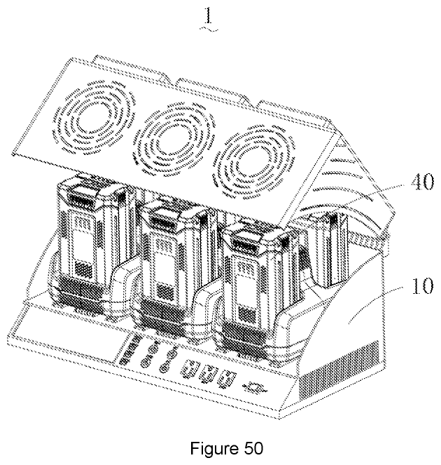

Please refer to FIG. 48 and FIG. 49. The disclosure further provides a charging device 12. The structure of the charging device 12 is substantially the same as that of the charging device 10, the difference is that a second connecting interface 1213 is arranged on the side wall 110 of the base body 103, and the second connecting port 2093 is arranged on the side wall 219 of the charger 20. The second connecting interface 1213 and the second connecting port 2093 may be sockets or elastic conductive terminals.

Please refer to FIG. 39 through FIG. 50, the disclosure further provides an energy supply device 1, the energy supply device 1 includes a battery pack 40 and a charging device 10/11/12, or includes a battery pack 40, a charger 20, and a charging device 10/11/12.

In the description of this specification, the description with reference to the terms “this embodiment”, “example”, “specific example”, etc. means that the specific features, structures, materials or characteristics described in combination with the embodiment or example is included in at least one of the embodiment or example of the disclosure. In this specification, the schematic representations of the terms mentioned above do not necessarily refer to the same embodiment or example. Moreover, the described specific features, structures, materials or characteristics can be combined in any one or several embodiments or examples in a suitable manner.

The embodiments of the disclosure disclosed above are only used to help explain the disclosure. The embodiments do not describe all the details in detail, nor do they limit the disclosure to be only specific implementations. Obviously, many modifications and changes can be made according to the content of this specification. This specification selects and specifically describes these embodiments in order to better explain the principles and practical applications of the disclosure, so that those skilled in the art can understand and use the disclosure well. The disclosure is only limited by the claims and their full scope and equivalents.

What is claimed is:

1. A charger, comprising:
a housing, defining a base and a supporting part, the supporting part being arranged on the base,
a charging position, arranged on the base and distributed around the supporting part,
a charging port, arranged on the charging position and matched with a battery pack, and
a first heat dissipation unit, arranged on the supporting part for heat dissipation of the battery pack.

2. The charger according to claim 1, wherein the supporting part comprising:
a first wall, arranged opposite to the battery pack, and
a second wall, located between two adjacent charging positions.

3. The charger according to claim 2, wherein the supporting part comprising:
a first vent, arranged on the first wall and used to allow air to flow in and out, and
a second vent, arranged on the second wall and used to allow air to flow in and out.

4. The charger according to claim 3 wherein
the charging position comprises a first charging position and a second charging position, the first charging position is arranged on one side of the supporting part, the second charging position is arranged on a side opposite to the first charging position, the first wall comprises a first side wall and a second side wall, the first vent comprises a first side vent hole arranged on the first side wall and a second side vent hole arranged on the second side wall.

5. The charger according to claim 4, wherein
the first charging position, the second charging position and the supporting part are arranged in a same line.

6. The charger according to claim 1, wherein
when the battery pack is connected with the charging position, the battery pack is inclined toward the supporting part.

7. The charger according to claim 6, wherein
an angle α is provided between the battery pack and the vertical direction, and the angle α is between 0° and 10°.

8. The charger according to claim 1, wherein
the charging position comprises a bearing wall to carry the battery pack, and an angle between the bearing wall and a horizontal plane is between 0° and 10°.

9. The charger according to claim 1, comprising:
a water collection groove, arranged on the base,
a drainage channel, communicated with the water collection groove to drain the water in the water collection groove out of the housing, and
a terminal assembly, arranged on the base, and the water collection groove being located on one or multiple sides of the terminal assembly to collect water in a vicinity of the terminal assembly.

10. The charger according to claim 1, wherein
the housing comprises a top wall, a bottom wall arranged opposite to the top wall, and a side wall located between the top wall and the bottom wall, the top wall, the bottom wall, and the side wall defines a receiving cavity, the receiving cavity comprises a first receiving cavity and a second receiving cavity, and the first receiving cavity houses the first heat dissipation unit, the first receiving cavity and the second receiving cavity are separated from each other.

11. The charger according to claim 10, comprising:
a circuit component, arranged in the second receiving cavity, and
a second heat dissipation unit, arranged in the second receiving cavity for heat dissipation of the circuit component.

12. The charger according to claim 11, wherein
a radiating fin is arranged in the second receiving cavity for heat dissipation of the circuit component,
the base is provided with an air inlet and an air outlet, the second heat dissipation unit drives air to enter from the air inlet and discharge from the air outlet, and a flow direction of the airflow is parallel to the radiating fin.

13. The charger according to claim 12, wherein
the first heat dissipation unit and the second heat dissipation unit are fans, the first heat dissipation unit is two fans, the second heat dissipation unit is two heat dissipation fans, the air inlet is provided with a fan, and the air outlet is provided with a fan.

14. The charger according to claim 1, wherein
a ratio of a height of the supporting part to a height of the base is greater than 1.5.

15. The charger according to claim 1, wherein
a height of the base is between 4 cm and 8 cm.

16. The charger according to claim 1, comprising:
a detection unit, used to detect a number of charging positions inserted into the battery pack, the detection unit obtaining status information of the battery pack corresponding to each charging position, wherein
when a number of battery packs connected with the charging position is 1, the battery pack at the charging position is charged with maximum power/current/voltage acceptable by the battery pack,
when the number of battery packs connected with the charging position is greater than 1, a control unit allocates power/current/voltage to the charging positions with the inserted battery pack one by one according to the number of the charging positions with the inserted battery pack and the status information of the battery pack.

17. The charger according to claim 1, comprising:
a transformer unit, connected with an external power supply,
a first charging unit, electrically connected to the transformer unit,
a second charging unit, electrically connected to the transformer unit, and
a control unit, electrically connected with the first charging unit and the second charging unit, the control unit obtaining internal information of the battery pack and controlling the first charging unit and the second charging unit to work in series or in parallel according to the internal information.

18. A control method of a charger, comprising:
obtaining a temperature of a battery pack,
stopping the charger charging and controlling the first heat dissipation unit to dissipate heat of the battery pack when the temperature of the battery pack is greater than or equal to a first temperature threshold,
charging the battery pack by the charger and controlling the first heat dissipation unit to dissipate heat of the battery pack when the temperature of the battery pack is less than the first temperature threshold.

19. A charging device, comprising:
a power input, electrically connected with an external power source,
a charging part, electrically connected with the power input, and
at least one charger, detachably connected to the charging part, the charger comprising:
a base,
a supporting part, arranged on the base,
a charging position, arranged on the base and distributed around the supporting part,
a charging port, arranged on the charging position and matched with the battery pack, and
a first heat dissipation unit, arranged on the supporting part for heat dissipation of the battery pack.

20. The charging device according to claim 19, further comprising:
an output unit, used to output electric power to the outside,
an inverter unit, used to invert the electric power obtained by the charging part from the battery pack through the charger into alternating current and output the alternating current through the output unit, and
a control unit, wherein
when the power input is connected with an external power, the control unit controls the charging part to supply power to the charger,
when the power input is disconnected from the external power, the control unit controls the inverter unit to work to output the power obtained by the charging part from the battery pack through the charger via the output unit.
